(19) United States
(12) Patent Application Publication
(10) Pub. No.: US 2025/0357347 A1
(43) Pub. Date: Nov. 20, 2025

(54) POWER TAP CONNECTIONS FOR NON-CMOS CIRCUITS UTILIZING CFET TECHNOLOGY

(71) Applicant: TAIWAN SEMICONDUCTOR MANUFACTURING COMPANY, LTD., Hsinchu (TW)

(72) Inventors: Kao-Cheng LIN, Hsinchu (TW); Jui-Chien HUANG, Hsinchu (TW); Pin-Dai SUE, Hsinchu (TW); Yen-Huei CHEN, Hsinchu (TW)

(21) Appl. No.: 19/287,579

(22) Filed: Jul. 31, 2025

Related U.S. Application Data
(63) Continuation of application No. 18/453,162, filed on Aug. 21, 2023.
(60) Provisional application No. 63/481,290, filed on Jan. 24, 2023.

(51) Int. Cl. H01L 23/528; H10D 84/01; H10D 84/03; H10D 84/83; H10D 84/85

(52) U.S. Cl. CPC H01L 23/5286; H10D 84/013; H10D 84/038; H10D 84/83; H10D 84/85

(57) ABSTRACT

A semiconductor device includes an intermediate layer including a plurality of conductive structures; and a plurality of isolation structures. The semiconductor device includes a first array of active regions on a first side of the intermediate layer. The semiconductor device includes a plurality of first gate structures, wherein corresponding first gate structures are between adjacent active regions of the first array of active regions. The semiconductor device includes a second array of active regions on a second side of the intermediate layer. The semiconductor device further includes a plurality of second gate structures, wherein corresponding second gate structures of the plurality of second gate structures are between adjacent active regions of the second array of active regions, each of the plurality of second gates is aligned with a corresponding first gate of the plurality of first gates, and a corresponding isolation structure is between aligned first and second gate structures.

### RELATED APPLICATIONS

This application is a continuation of U.S. application Ser. No. 18/453,162, filed Aug. 21, 2023, which claims priority from U.S. Provisional Patent Application No. 63/481,290, filed Jan. 24, 2023, the entire contents of which are incorporated herein by reference.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, improved performance, and lower costs, challenges from both fabrication and design issues have resulted in the development of a number of three-dimensional designs including, for example, Metal-Oxide-Silicon Field Effect Transistors (MOS-FET), Field Effect Transistors (FET), Fin Field Effect Transistor (FinFET), Gate-All-Around (GAA) devices (nanowires/nanosheets), GAA devices configured as Complementary Field Effect Transistor (CFET) devices, and Multi-Bridge Channel Field Effect Transistor (MBCFET) devices (nanosheets).

Integrated circuit (IC) manufacturing processes are divided into front-end-of-line (FEOL) processing and back-end-of-line (BEOL) processing, in some instances. FEOL processes generally encompass those processes related to fabricating functional elements, such as transistors and resistors, in or on a semiconductor substrate. For example, FEOL processes typically include forming isolation features, gate electrodes and dielectrics, and source and drain features (also referred to as source/drain or S/D features). BEOL processes generally encompass those processes related to fabricating a multilayer interconnect (MLI) features that interconnects the functional IC elements and structures fabricated during FEOL processing to provide connection to and enable operation of the resulting IC devices.

Process and structural modifications that reduce the process complexity and/or size of features associated with, for example, gate electrodes and related structures and multilayer interconnect structures, tend to reduce the overall size of the IC devices, improve cycle time, and/or improve yield and reliability. Some devices utilize the backside of the wafer for forming a backside power grid (BPG) (or a buried power rail (BPR)) and/or a backside ground grid (BGG) for supplying power and/or ground connections to active circuitry formed on the frontside of the wafer, improving device area utilization, and reducing current/resistance (IR) losses during device operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a CFET region of a semiconductor device during a manufacturing process, according to some embodiments.

FIG. 1B is a top view of a CFET region of a semiconductor device during a manufacturing process, according to some embodiments of FIG. 1A.

FIG. 1C is a bottom view of a CFET region of a semiconductor device during a manufacturing process, according to some embodiments of FIG. 1A.

FIG. 2A is a cross-sectional view of a CFET region of a semiconductor device during a manufacturing process, according to some embodiments.

FIG. 2B is a top view of a CFET region of a semiconductor device during a manufacturing process, according to some embodiments of FIG. 2A.

FIG. 2C is a bottom view of a CFET region of a semiconductor device during a manufacturing process, according to some embodiments of FIG. 2A.

FIG. 2D is a cross-sectional view of a portion of a CFET region of a semiconductor device during a manufacturing process, according to some embodiments of FIG. 2A.

FIG. 3A is a cross-sectional view of a CFET region of a semiconductor device during a manufacturing process, according to some embodiments.

FIG. 3B is a top view of a CFET region of a semiconductor device during a manufacturing process, according to some embodiments of FIG. 3A.

FIG. 3C is a bottom view of a CFET region of a semiconductor device during a manufacturing process, according to some embodiments of FIG. 3A.

FIG. 4 is a cross-sectional view of a CFET region of a semiconductor device during a manufacturing process, according to some embodiments.

FIG. 5 is a cross-sectional view of a CFET region of a semiconductor device during a manufacturing process, according to some embodiments.

FIG. 6A is a cross-sectional view of a portion of a CFET region of a semiconductor device during a manufacturing process, according to some embodiments of FIG. 5.

FIG. 6B is schematic diagram of a circuit corresponding to a CFET region according to some embodiments of FIG. 6A.

FIG. 7A is a flowchart of a portion of a manufacturing process control system for the production of CFET devices according to some embodiments.

FIG. 7B is a flowchart of a portion of a manufacturing process control system for the production of CFET devices according to some embodiments.

FIG. 8 is a is a block diagram of an electronic process control (EPC) system useful for the production of CFET devices according to some embodiments.

FIG. 9 is a block diagram of a system for manufacturing CFET devices according to some embodiments.

FIG. 10 is a block diagram of fabrication facility operations for manufacturing of IC devices according to some embodiments.

FIG. 11 is a schematic perspective view of a stack of semiconductor devices in a CFET configuration, in accordance with some embodiments.

FIG. 12 is a schematic perspective view of a CFET configuration, in accordance with some embodiments.

FIGS. 13A-13D are cross-sectional views of a CFET region of a semiconductor device during a manufacturing process, according to some embodiments.

FIG. 14 is a cross-sectional view of a semiconductor device including CFET structures, according to some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first are formed in direct contact the second features and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The structures and methods detailed below relate to improved structures, designs, and manufacturing methods for CFET IC devices that include backside power grid (BPG) and/or a backside ground grid (BGG) for supplying power and/or ground connections to active circuitry formed while reducing or eliminating the use of vias for establishing the power and/or ground connections and simplifying the MLI fabrication during BEOL operations. Accordingly, in some embodiments adopting structures and methods that tend to reduce or eliminate the patterning, etch, deposition, and removal processing steps involved in forming vias and related conductive patterns. These process changes will, in turn, tend to improve the utilization of the substrate area and increase the manufacturing yield and/or performance of the resulting integrated circuits.

Although the structures and methods will be discussed in terms of CFET structures devices, one of ordinary skill in the art would understand that the structures and methods are not so limited and certain aspects of the embodiments discussed are suitable for inclusion in manufacturing processes for other classes and configurations of IC devices. The structures and methods disclosed herein are equally applicable to various manufacturing processes used in achieving the NMOS/PMOS vertical stack structures including both monolithic CFET manufacturing processes and sequential CFET manufacturing processes.

In some embodiments a monolithic CFET manufacturing process (or process flow) starts with the formation of an epitaxial layer that will serve as the bottom channel (or lower tier), followed by the formation of an intermediate sacrificial layer, and then the formation of an epitaxial layer that will serve as the top channel (or upper tier). Although the processing sequence is straightforward, in some embodiments the stacked structure results in very high-aspect-ratio vertical structures that presents challenges for the operations used to pattern, etch, and/or deposit the associated structures including, for example, fins, gates, spacers, and source/drain contacts.

Alternatively, in some embodiments a sequential CFET manufacturing process is utilized in which the bottom channel devices are processed up to the contact level, after which a separate semiconductor layer is positioned above the bottom channel devices using, for example, a wafer transfer using a wafer-to-wafer bonding technique. In some embodiments, the top channel devices are then fabricated before the wafer transfer while in other embodiments the top channel devices fabricated after the wafer transfer. Once the top channel devices are complete, the top channel and bottom channel gates are connected. Although a sequential CFET manufacturing process is, in some respects, less challenging than a monolithic CFET manufacturing process, the wafer transfer operation includes specific challenges absent from the monolithic process.

In some embodiments, CFET structures are used in manufacturing one or more of the peripheral circuits used during operation of memory arrays provided elsewhere on the IC device. In some embodiments, these CFET peripheral circuits include one or more of write drivers, pre-chargers, sense amplifiers (SA), and/or power switches. In some embodiments, utilizing CFET designs for these peripheral circuits increases the chip area available for the memory arrays, reduces the need for and/or the size of backside contact via structures and provides additional options for contacting backside power and ground circuits with reduced the current/resistance (IR) losses associated with the peripheral circuits.

In some embodiments, a stack of semiconductor devices comprises a top or upper semiconductor device that is physically stacked over a bottom or lower semiconductor device. A CFET structure includes stacked upper and lower semiconductor devices of different conductivity types. For simplicity, a stack of semiconductor devices is sometimes referred to as a device stack. Depending on the device design, the included device stacks comprise stacked semiconductor devices of the same conductivity type and/or device stacks in which the stacked semiconductor devices are of different conductivity types. In some embodiments, by configuring semiconductor devices in device stacks, the required chip area is reduced by up to 50%.

In some embodiments, semiconductor devices in a device stack are electrically coupled in series, which is advantageous in high voltage applications. In some embodiments, semiconductor devices in a device stack are electrically coupled in parallel, which is advantageous in high current applications. In some embodiments, device stacks are manufactured by CFET processes, with little or no changes. In at least one embodiment, device stacks are advantageously applicable to core devices or core regions of an IC device. Further benefits of device stacks, in one or more embodiments, include improvements in power, performance and/or area (PPA) of the resulting IC devices, or the like.

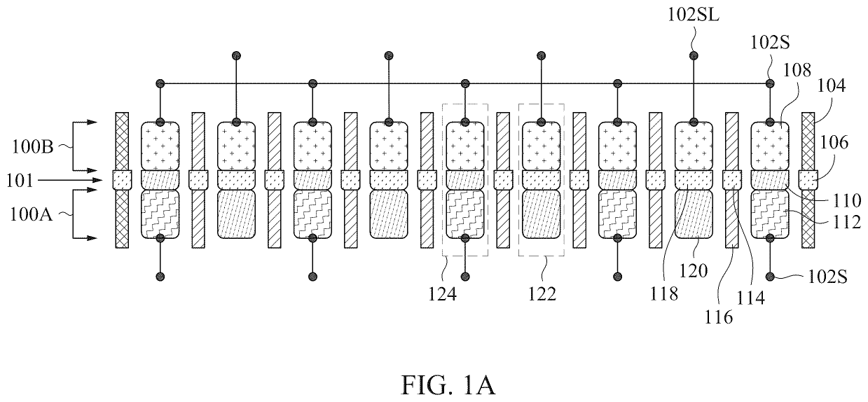

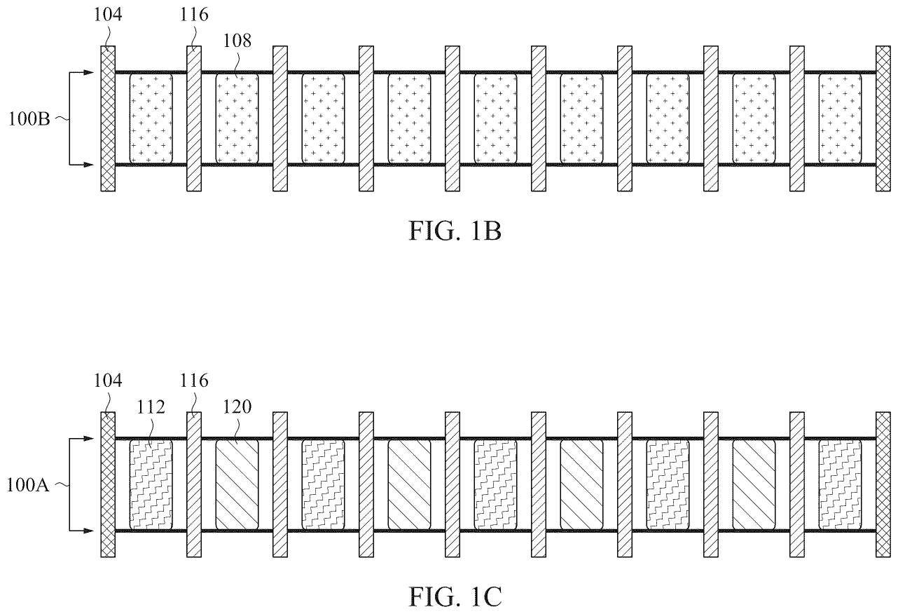

FIG. 1A is a cross-sectional view of a CFET region of a semiconductor device during a manufacturing process according to some embodiments in which a first array of lower channel structures 100A is formed on a substrate. In some embodiments, the first array of structures includes an alternating pattern of PMOS active regions 120 and low resistance materials. These PMOS active regions 120 and low resistance materials 112 are separated from each other by a plurality of gate structures 116 and, in some embodiments, are formed between terminal isolation structures 104. In some embodiments, the terminal isolation structures are configured as polysilicon over diffusion edge (PODE) or common polysilicon over diffusion edge (CPODE) structures. In some embodiments, an array of intermediate structures 101 including both isolation structures 106, 114, 118, and conductive structures 110 is then provided above the lower channel structures 100A. In some embodiments, in which a second array of upper channel structures 100B is formed on the array of intermediate structures 101 with the upper channel structures 100B comprising a plurality of NMOS active regions 108. These NMOS active regions 108 of upper channel structures 100B are separated from each other by a plurality of gate structures 116 and, in some embodiments, are formed between terminal isolation structures 104.

In some embodiments according to FIG. 1A, after formation of the upper channel structures 100B the resulting configurations of stacked structures comprising a lower channel structure, an intermediate structure, and an upper channel structure include both an N on P structure 122 (or N on P vertical assembly) and an N on TAP structure 124 (or N on conductor structure). In some embodiments, each N on P structure 122 is connected to a signal line 102SL while each N on TAP structure 124 is used for establishing an electrical connection between a backside voltage source, e.g., a source voltage 102S (Vss) and the frontside circuitry. In some embodiments, one or more of the PMOS active regions 120 in the lower channel structures 100A area are not configured as elements of a functional transistor and are, in some instances, referred to as dummy PMOS regions (or simply dummy regions or dummy structures), and serve to support and align the NMOS active regions 108 arranged in the upper channel structures 100B. In other embodiments, both the PMOS active regions 120 and the NMOS active regions in an N on P structure 122 are configured as elements of separate functional transistors.

FIG. 1B is a top view of a CFET region of a semiconductor device during a manufacturing process, according to the embodiments of FIG. 1A in which the upper surfaces of the NMOS active regions 108 of the upper channel structures 100B, the gate structures 116, and the terminal isolation structures 104 are visible.

FIG. 1C is a bottom view of a CFET region of a semiconductor device during a manufacturing process, according to the embodiments of FIG. 1A in which the lower surfaces of the PMOS active regions 120 and the low resistance material 112 of the lower channel structures 100A, the gate structures 116, and the terminal isolation structures 104 are visible.

In some embodiments, isolation structures may include one or more high-κ dielectric material includes one or more of HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, SiOxNy, and combinations thereof, or another suitable insulating material. In some embodiments, the conductive structures and/or the low resistance materials will be selected from one or more of Si, Ti, Ag, Al, TiAlN, TaC, TaCN, TaSiN, Mn, Zr, TiN, TaN, Ru, Mo, Al, WN, Cu, W, Re, Ir, Co, Ni, and other suitable conductive materials and combinations and alloys thereof. The insulating/dielectric and conductive materials may be formed by atomic layer deposition (ALD), physical vapor deposition (PVD), chemical vapor deposition CVD, plasma enhanced chemical vapor deposition (PECVD), thermal oxidation, self-aligned monolayer (SAM) deposition and/or one or more other suitable method(s) and may be patterned using pattern/etch, etchback, or chemical mechanical polishing (CMP) processes to obtain a predetermined pattern of materials comprising semiconductor devices.

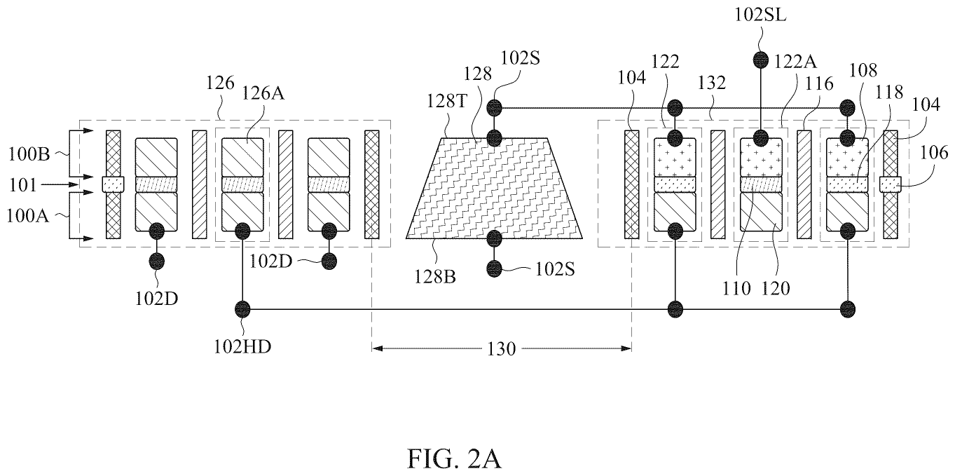

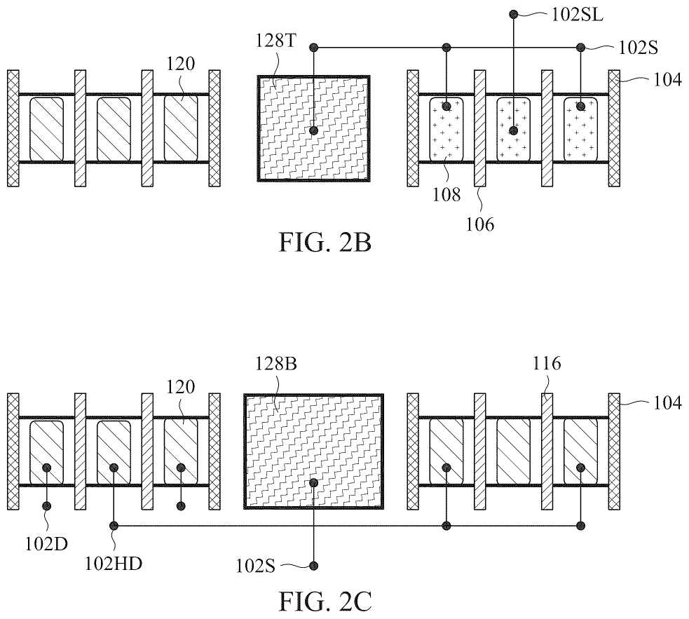

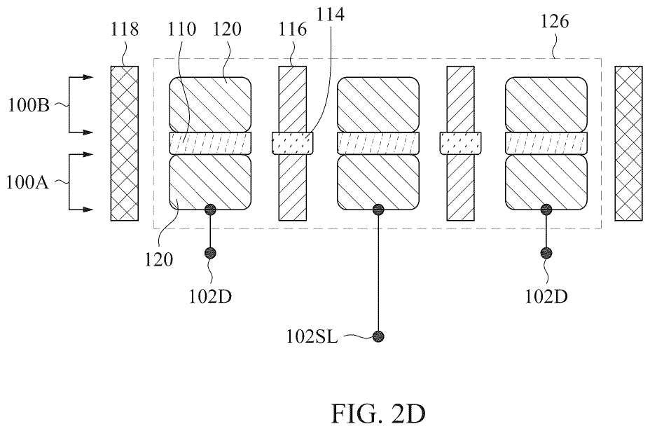

FIG. 2A is a cross-sectional view of a CFET region of a semiconductor device during a manufacturing process, according to some embodiments according to some embodiments in which a first array of lower channel structures 100A is formed on a substrate. In some embodiments, the first array of structures includes two distinct sub-arrays of PMOS active regions 120 separated by a via structure 128 (or TAP structure). These PMOS active regions 120 are separated from each other by a plurality of gate structures 116 and, in some embodiments, the subarrays are formed between terminal isolation structures 104. In some embodiments, an array of intermediate structures 101 including both isolation structures 106, 118, and conductive structures 110 is then provided above the lower channel structures 100A. In some embodiments, in which a second array of upper channel structures 100B is formed on the array of intermediate structures 101 with the upper channel structures 100B comprising a plurality of PMOS active regions 120 and NMOS active regions 108. These PMOS active regions 120 and NMOS active regions 108 of upper channel structures 100B are separated from each other by a plurality of gate structures 116 and, in some embodiments, are formed between terminal isolation structures 104.

In some embodiments according to FIG. 2A, after formation of the upper channel structures 100B the resulting configurations of stacked structures comprising a lower channel structure, an intermediate structure, and an upper channel structure include P on P conductive structures 126A that are configured as a power switch structure 126 (a P-rich region). In the power switch structure 126, the P on P conductive structures 126A are connected to a drain voltage 102D (Vdd) or, in some embodiments, one or more of the P on P conductive structures 126A are connected to a separate virtual drain voltage 102HD (VddHD) line. In some embodiments, the virtual drain voltage 102HD is a voltage greater than that of the drain voltage 102D and in other embodiments, a virtual drain voltage 102HD. In some embodiments the virtual drain voltage 102HD is a virtual power line that is coupled to a power supply through one or more transistor switches (not shown) for controlling application of a drain voltage to the connected P on P conductive structures 126A.

In some embodiments according to FIG. 2A, after formation of the upper channel structures 100B the resulting configurations of stacked structures comprising a lower channel structure, an intermediate structure, and an upper channel structure include an N on P structure 122 in which the NMOS active region 108 and the PMOS active region 120 are separated by an isolation structure 118 and an N on P conductive structure 122A in which the NMOS active region 108 and the PMOS active region 120 are separated by a conductive structure 110 with both the N on P structure 122 and the N on P conductive structure 122A combined in an N on P region 132. In some embodiments, the N on P region 132 includes one or more N on P structures 122 in which the NMOS active regions 108 are connected to a source voltage 102S (Vss) or a signal line 102SL and the PMOS active regions 120 are connected to a drain voltage (not shown) or a virtual drain voltage 102HD (VddHD).

In some embodiments according to FIG. 2A, a via structure 128 (or TAP structure) is arranged between the power switch structure 126 and the N on P region 132 to provide an additional connection between a backside voltage supply (not shown) and frontside devices. In some embodiments, the via structure 128 (or TAP structure) serves an additional purpose of separating the power switch structure 126 and the N on P region 132 and defining a P to N transition region 130 between the power switch structure 126 and the N on P region 132 that reduces interference between the power switch structure 126 and the N on P region 132 and tends to improve performance of the resulting device.

FIG. 2B is a top view of a CFET region of a semiconductor device during a manufacturing process, according to the embodiments of FIG. 2A in which the upper surfaces of the PMOS active regions 120 and NMOS active regions 108 of the upper channel structures 100B are visible along with the top surfaces of the via TAP structure 128T, gate structures 116, and the terminal isolation structures 104.

FIG. 2C is a bottom view of a CFET region of a semiconductor device during a manufacturing process, according to the embodiments of FIG. 2A in which the upper surfaces of the PMOS active regions 120 and NMOS active regions 108 of the lower channel structures 100A are visible along with the bottom surfaces of the via TAP structure 128B, gate structures 116, and the terminal isolation structures 104.

FIG. 2D is a cross-sectional view of an alternative configuration of a portion of a CFET region of a semiconductor device during a manufacturing process, according to the embodiments of FIG. 2A in which at least one of the P on P conductive structures 126A are connected to a signal line 102SL.

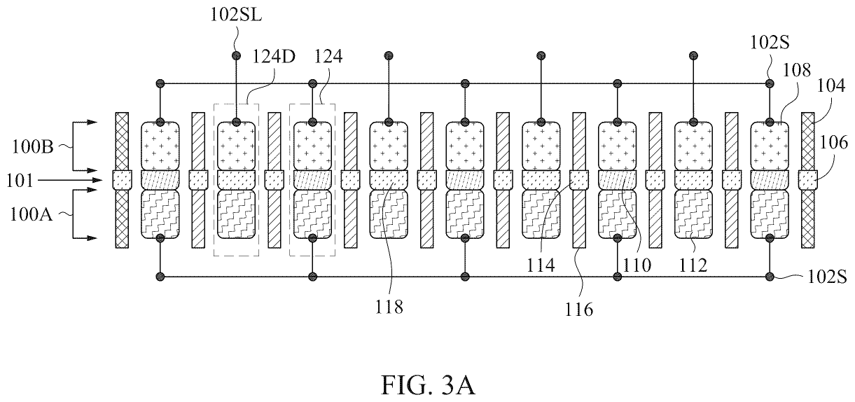

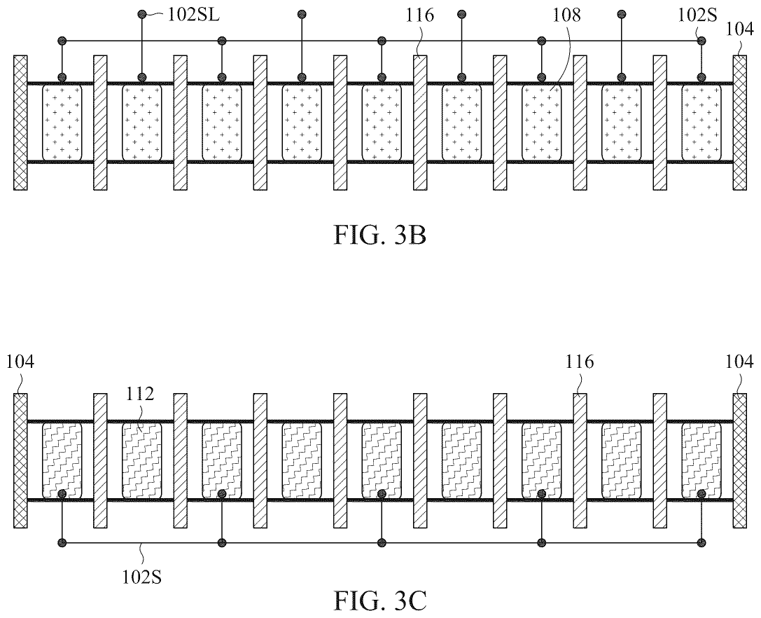

FIG. 3A is a cross-sectional view of a CFET region of a semiconductor device during a manufacturing process, according to some embodiments, in which a first array of lower channel structures 100A is formed on a substrate. In some embodiments, the first array of lower channel structures 100A includes an alternating pattern of low resistance materials 112. These low resistance materials 112 are separated from each other by a plurality of gate structures 116 and, in some embodiments, are formed between terminal isolation structures 104. In some embodiments, an array of intermediate structures 101 including both isolation structures 106, 114, 118, and conductive structures 110 is then provided above the lower channel structures 100A. In some embodiments, a second array of upper channel structures 100B is formed on the array of intermediate structures 101 with the upper channel structures 100B comprising a plurality of NMOS active regions 108. These NMOS active regions 108 of upper channel structures 100B are separated from each other by a plurality of gate structures 116 and, in some embodiments, are formed between terminal isolation structures 104.

In some embodiments according to FIG. 3A, after formation of the upper channel structures 100B the resulting configurations of stacked structures comprising a lower channel structure, an intermediate structure, and an upper channel structure include both an N on TAP structures 124 (or N on conductor structure) and N on dummy structures 124D. In some embodiments, the NMOS active region 108 of each N on TAP structure 124 includes an NMOS active region 108 from the upper channel structures 100B, a conductive structure 110 from the intermediate structures 101, and a low resistance material 112 from the lower channel structures 100A. The N on TAP structure 124 provides a conductive path whereby a voltage applied to the low resistance material 112 from a backside power grid or ground grid (not shown), for example, a source voltage 102S (Vss), is connected to frontside devices incorporating NMOS active regions from the upper channel structures 100B. Conversely, the N on dummy structure 124D includes an NMOS active region 108 from the upper channel structures 100B, an isolation structure 118 from the intermediate structures 101, and a low resistance material 112 (the dummy structure) from the lower channel structures 100A. The isolation structure 118 in the N on dummy structure 124D prevents voltage applied to the lower surface of the low resistance material 112 from being communicated to the NMOS active region 108. Similarly, the isolation structure 118 in the N on dummy structure 124D prevents a source voltage 102S or a signal line 102SL applied to the upper surface of the NMOS active region 108 from being communicated to the low resistance material 112, while allowing the NMOS active region 108 from the upper channel structures 100B to be incorporated into an active device.

FIG. 3B is a top view of a CFET region of a semiconductor device during a manufacturing process, according to the embodiments of FIG. 3A in which the upper surfaces of the NMOS active regions 108 of the upper channel structures 100B, the gate structures 116, and the terminal isolation structures 104 are visible.

FIG. 3C is a bottom view of a CFET region of a semiconductor device during a manufacturing process, according to the embodiments of FIG. 3A in which the lower surfaces of the low resistance materials 112 of the lower channel structures 100A, the gate structures 116, and the terminal isolation structures 104 are visible.

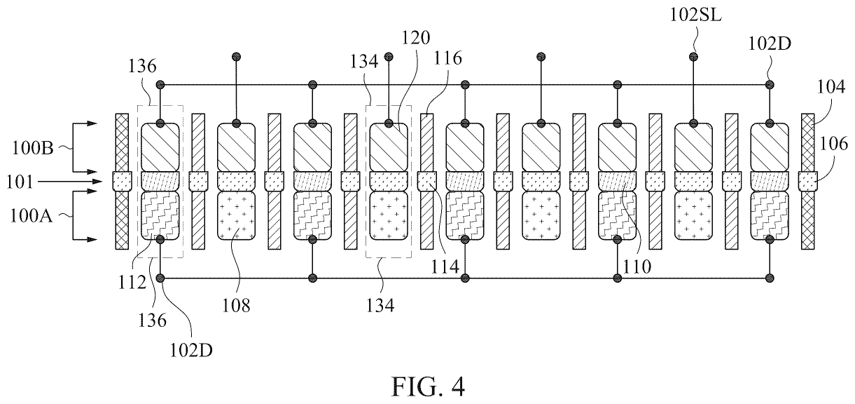

FIG. 4 is a cross-sectional view of a CFET region of a semiconductor device during a manufacturing process according to some embodiments in which a first array of lower channel structures 100A is formed on a substrate. In some embodiments, the first array of lower channel structures 100A includes an alternating pattern of NMOS active regions 108 and low resistance materials 112. These NMOS active regions 108 and low resistance materials 112 are separated from each other by a plurality of gate structures 116 and, in some embodiments, are formed between terminal isolation structures 104. In some embodiments, an array of intermediate structures 101 including both isolation structures 106, 114, 118, and conductive structures 110 is then provided above the lower channel structures 100A. In some embodiments, in which a second array of upper channel structures 100B is formed on the array of intermediate structures 101 with the upper channel structures 100B comprising a plurality of PMOS active regions 120. These PMOS active regions 120 of upper channel structures 100B are separated from each other by a plurality of gate structures 116 and, in some embodiments, are formed between terminal isolation structures 104.

In some embodiments according to FIG. 4, after formation of the upper channel structures 100B the resulting configurations of stacked structures comprising a lower channel structure, an intermediate structure, and an upper channel structure include both a P on N structure 134 (or a P on dummy structure 134D) and a P on TAP structure 136 (or P on conductor structure or vertical assembly). In some embodiments, each P on N structure 134 is connected to a signal line 102SL while each P on TAP structure 136 is used for establishing an electrical connection between a backside voltage supply (not shown), specifically a drain voltage 102D, for transferring the connected voltage Vdd to the frontside of the device and the frontside circuitry. In some embodiments, one or more of the NMOS active regions 108 in the lower channel structures 100A area are not configured as elements of a functional transistor and are, in some instances, referred to as dummy NMOS regions (or simply dummy regions or structures), and serve to support and align the PMOS active regions 120 arranged in the upper channel structures 100B. In other embodiments, both the PMOS active regions 120 and the NMOS active regions in a P on N structure 134, are configured as elements of separate functional transistors.

In some embodiments, the PMOS active region 120 of each P on TAP structure 136 includes a PMOS active region 120 from the upper channel structures 100B, a conductive structure 110 from the intermediate structures 101, and a low resistance material 112 from the lower channel structures 100A. The P on TAP structure 136 (or vertical assembly), provides a conductive path whereby a voltage applied to the low resistance material 112 from a backside power grid or ground grid (not shown), for example, a drain voltage 102D (Vdd) is connected through the P on TAP structure 136 (or vertical assembly), to frontside devices incorporating PMOS active regions 120 from the upper channel structures 100B.

The isolation structure 118 in the P on N structure 134 and the P on dummy structure 134D prevents voltage applied to the lower surface of the backside NMOS active region 108 from being communicated to the frontside PMOS active region 120. Similarly, the isolation structure 118 in the P on dummy structure 134D prevents a drain voltage 102D or a voltage from a signal line 102SL applied to the upper surface of the frontside PMOS active region 120 from being communicated to the backside NMOS active region 108, while allowing the PMOS active region 120 from the upper channel structures 100B to be incorporated into a functional transistor or other active device. In some embodiments, one or more of the NMOS active regions 108 from the lower channel structures 100A in the P on N structure 134 are incorporated into one or more functional transistors or other active devices comprising elements from the lower channel structures 100A. In some embodiments, while similarly configured to the P on N structure 134, in the P on dummy structures 134D the NMOS active region 108 from the lower channel structures 100A is utilized only for positioning the frontside PMOS active region 120 from the upper channel structures 100B for inclusion in a functional device while the backside NMOS active region 108 is not incorporated into a functional transistor or other active device, hence the “dummy” designation for the unconnected NMOS active region 108.

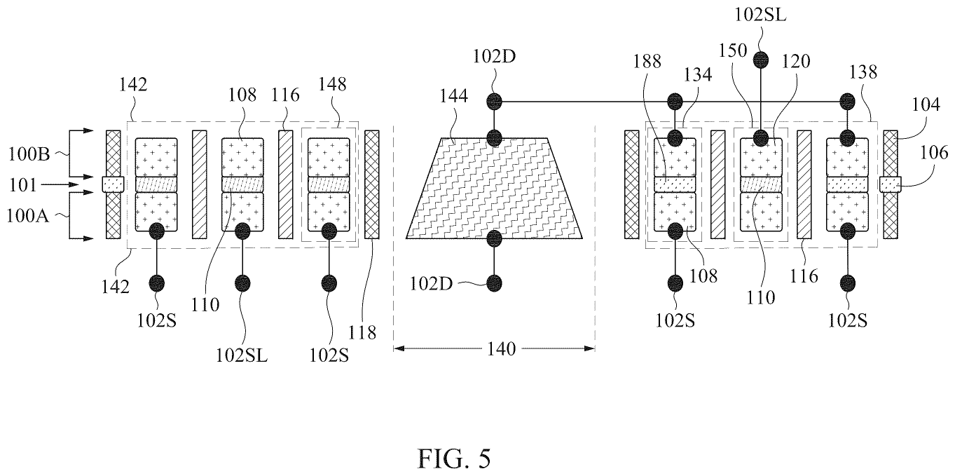

FIG. 5 is a cross-sectional view of a CFET region of a semiconductor device during a manufacturing process according to some embodiments in which a first array of lower channel structures 100A is formed on a substrate. In some embodiments, the first array of lower channel structures 100A includes two distinct sub-arrays, a first sub-array 142 and a second sub-array 138, separated by a via structure 144 (TAP structure). In some embodiments, the lower channel structures 100A of both the first sub-array 142 and the second sub-array 138 include NMOS active regions 108 separated by gate structures 116 and are formed between terminal isolation structures 104.

In some embodiments, an array of intermediate structures 101 including both isolation structures 106, 118, and conductive structures 110 is then provided above the lower channel structures 100A. In some embodiments a second array of upper channel structures 100B is formed on the array of intermediate structures 101 with the upper channel structures 100B comprising a plurality of NMOS active regions 108 in a first sub-array 142 and PMOS active regions 120 on the second sub-array 138. These PMOS active regions 120 and NMOS active regions 108 of the upper channel structures 100B are separated from each other by a plurality of gate structures 116 and, in some embodiments, are formed between terminal isolation structures 104.

In some embodiments according to FIG. 5, after formation of the upper channel structures 100B the resulting configurations of stacked structures comprising a lower channel structure, an intermediate structure, and an upper channel structure include N on N conductive structures 148 that are configured as a ground switch structure 142A (an N-rich region). In the ground switch structure 142A, a portion of the N on N conductive structures 148 are connected to a source voltage 102S (Vss) or, in some embodiments, one or more of the N on N conductive structures 148 are connected to a separate signal line 120SL.

In some embodiments according to FIG. 5, after formation of the upper channel structures 100B the resulting configurations of stacked structures comprising a lower channel structure, an intermediate structure, and an upper channel structure include a P on N structure 134 in which the NMOS active region 108 and the PMOS active region 120 are separated by an isolation structure 118 and a P on N conductive structure 150 in which the PMOS active region 120 and the NMOS active region 108 are separated by a conductive structure 110 with both the P on N structure 134 and the P on N conductive structure 150 combined in a P on N region comprising a second sub-array 138. In some embodiments, the second sub-array 138 includes one or more P on N structures 134 (or vertical assemblies) in which the NMOS active regions 108 are connected to a source voltage 102S (Vss) and the PMOS active regions 120 are connected to a drain voltage 102D or a signal line 102SL.

In some embodiments according to FIG. 5, a via structure 144 (TAP structure) is arranged between the ground switch structure 142A and the second sub-array 138 to provide an additional connection between a backside drain voltage and frontside devices. In some embodiments, the via structure 144 serves an additional purpose of separating the ground switch structure 142A and the P on N region in the second sub-array 138 and defining an N to P transition region 140 between the ground switch structure 142A and the P on N region in the second sub-array 138 that reduces interference between the ground switch structure 142A and the P on N region in the second sub-array 138 and tends to improve performance of the resulting device.

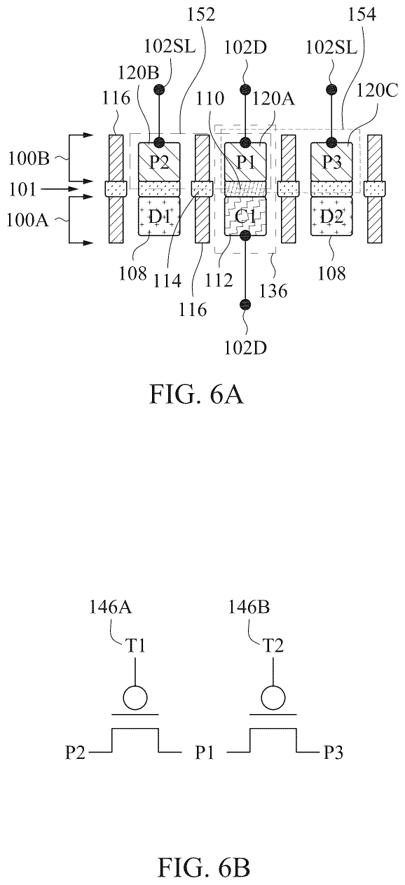

FIG. 6A is a cross-sectional view of a portion of a CFET region of a semiconductor device during a manufacturing process, according to some embodiments of FIG. 5 in which the PMOS active regions 120A, 120B, 120C (the PMOS top channel structures 154) in the P on N region are configured to form a first transistor with PMOS active region 120B and a second transistor with PMOS active region 120C with the PMOS active region 120A of the P on TAP structure 136 serving as a common drain for the first and second transistors.

FIG. 6B is a schematic diagram of a circuit corresponding to a CFET region according to some embodiments of FIG. 6A in which first transistor T1 146A and second transistor T2 146B, utilize the PMOS active areas of the CFET configuration of FIG. 6A.

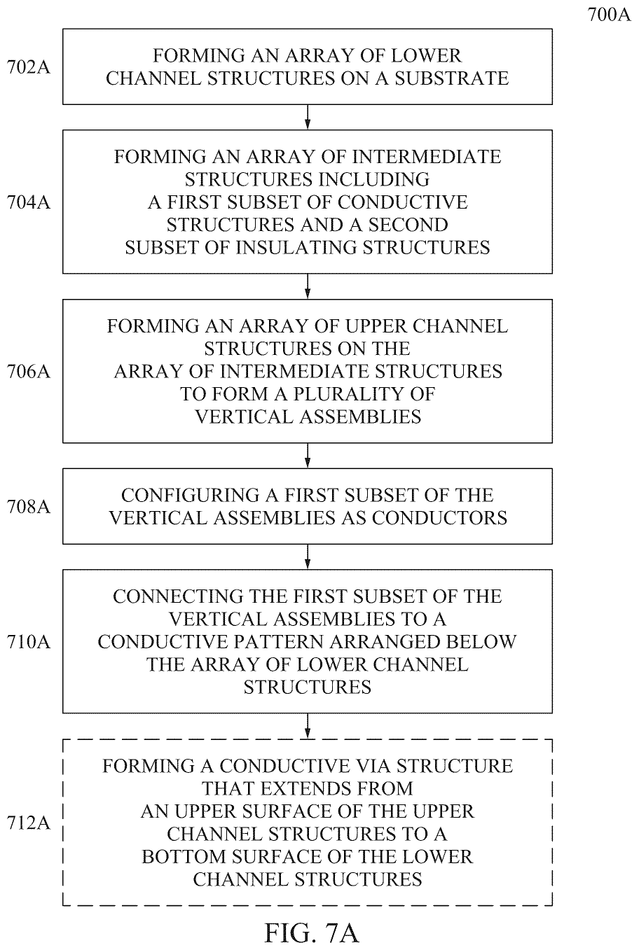

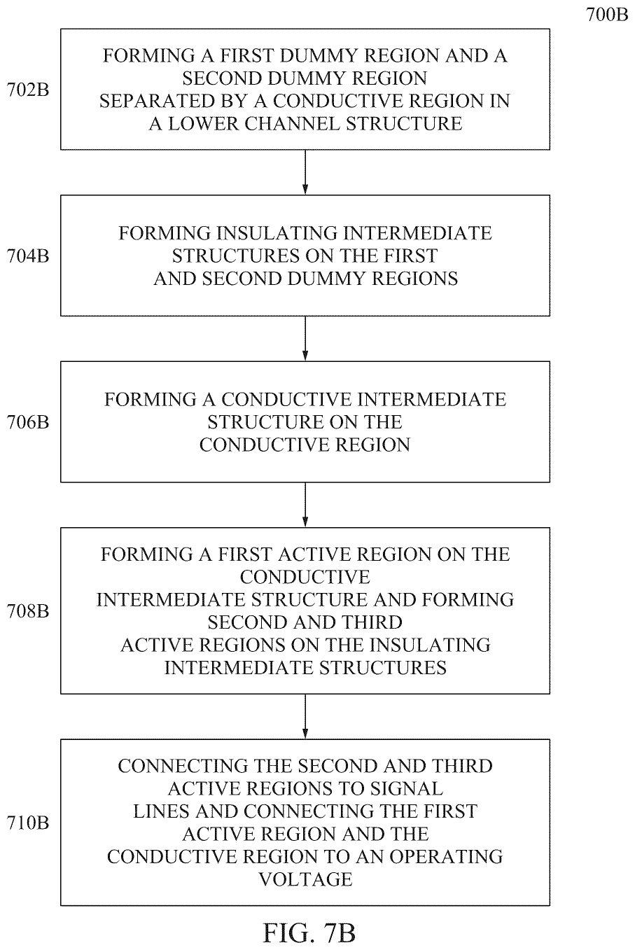

FIG. 7A is a flowchart of a portion of a manufacturing process 700A for the production of CFET devices according to some embodiments.

During operation 702A, an array of lower channel structures 100A are formed on a substrate. In some embodiments the lower channel structures are selected from a group consisting of NMOS active regions 108, PMOS active regions 120, and low resistance materials 112. In some embodiments, these lower channel structures are separated by gate structures 116 and terminal isolation structures 104 are used to isolate the lower channel structures 100A.

During operation 704A, an array of intermediate structures 101 are formed on the lower channel structures 100A. In some embodiments the array of intermediate structures includes a first subset of conductive structures and a second subset of insulating structures that are formed on predetermined members of the lower channel structures 100A. In some embodiments, these lower channel structures are separated by gate structures 116 and/or by terminal isolation structures 104 and/or intermediate isolation structures 106.

During operation 706A, an array of upper channel structures 100B are formed on the array of intermediate structures. In some embodiments the upper channel structures are selected from a group consisting of NMOS active regions 108, PMOS active regions 120, and low resistance materials 112. In some embodiments, these upper channel structures are separated by gate structures 116 with terminal isolation structures 104 being used to isolate the upper channel structures 100B.

During operation 708A, at least one vertical assemblies comprising a combination of an active region from the upper channel structures, a conductive structure from the intermediate structures, and a low resistance structure from the lower channel structures cooperate to form a conductor that provides a conductive path between the backside and the frontside of the device.

During operation 710A, the conductor is connected to a backside voltage supply, a source voltage 102S or a drain voltage 102D, for transferring the connected voltage Vss, Vdd to the frontside of the device.

During optional operation 712A, the via structure 128, 144 is formed between a first sub-array of the upper channel structures 100B and a second array of the upper channel structures 100B with the via structure 128, 144 extending from a first plane defined by a top surface of the upper channel structures 100B to a second plane defined by a bottom surface of the lower channel structures 100A. The via structure 128, 144 is connected to backside voltage supply, a source voltage 102S or a drain voltage 102D, for transferring the connected voltage Vss, Vdd to the frontside of the device.

FIG. 7B is a flowchart of a portion of a manufacturing process 700B for the production of CFET devices according to some embodiments.

During operation 702B, first and second dummy regions with a low resistance material positioned between the two dummy regions are formed as part of an array of lower channel structures 100A on a substrate. In some embodiments the dummy regions are selected from NMOS active regions, PMOS active regions, low resistance materials, insulating structures, and combinations thereof. In some embodiments the array of lower channel structures 100A are separated by gate structures 116 and/or by terminal isolation structures 104.

During operation 704B, an array of intermediate structures 101 are formed on the lower channel structures 100A with the array of intermediate structures for some embodiments including intermediate isolation structures 118 formed on the two dummy regions.

During operation 706B, one or more intermediate conductive structures 110 are formed on one or more of the lower channel structures 100A including the low resistance material 112 arranged between the first and second dummy regions.

During operation 708B, an array of upper channel structures 100B are formed on the array of intermediate structures 101. In some embodiments the upper channel structures are selected from a group consisting of NMOS active regions 108, PMOS active regions 120, and low resistance materials 112. In some embodiments, these upper channel structures are separated by gate structures 116 with terminal isolation structures 104 being used to isolate the array of upper channel structures 100B.

During operation 710B, electrical contact is established between signal lines 102SL and a subset of the active regions included in the array of upper channel structures 100B that are positioned above the dummy regions. Further, during operation 710B electrical contact is established between a backside voltage supply, supplying a source voltage 102S or a drain voltage 102D, for transferring the connected voltage Vss, Vdd to the frontside of the device and active region(s) arranged above at least one of the array of lower channel structures arranged between the dummy regions.

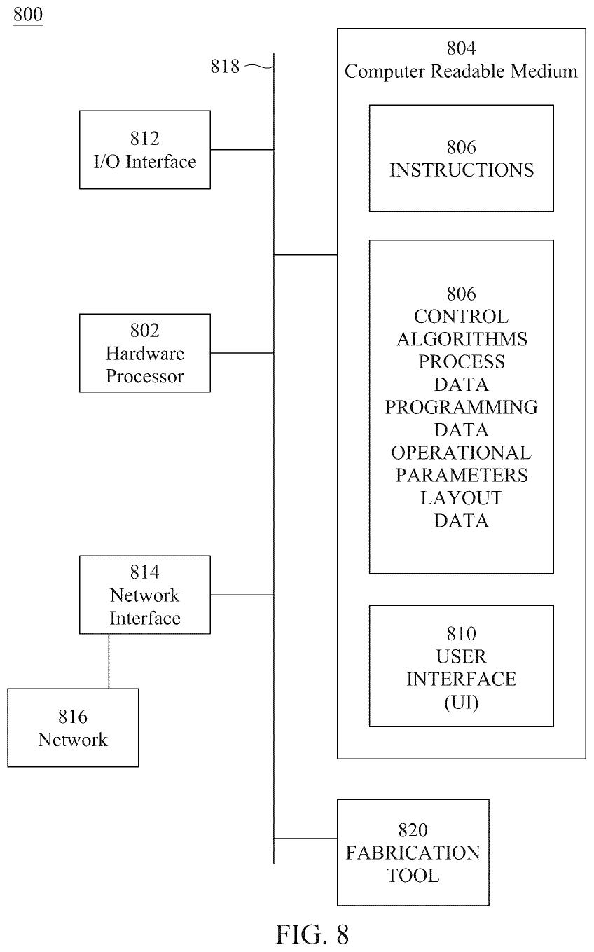

FIG. 8 is a block diagram of an electronic process control (EPC) system 800, in accordance with some embodiments. Methods used for generating cell layout diagrams corresponding to some embodiments of the FET device structures detailed above, particularly with respect to the addition and placement of the electrical contacts, thermal contacts, active metal patterns, dummy metal patterns, and other heat dissipating structures may be implemented, for example, using EPC system 800, in accordance with some embodiments of such systems.

In some embodiments, EPC system 800 is a general purpose computing device including a hardware processor 802 and a non-transitory, computer-readable, storage medium 804. Computer-readable storage medium 804, amongst other things, is encoded with, i.e., stores, computer program code (or instructions) 806, i.e., a set of executable instructions. Execution of computer program code 806 by hardware processor 802 represents (at least in part) an EPC tool which implements a portion or all of, e.g., the methods described herein in accordance with one or more (hereinafter, the noted processes and/or methods).

Hardware processor 802 is electrically coupled to computer-readable storage medium 804 via a bus 818. Hardware processor 802 is also electrically coupled to an I/O interface 812 by bus 818. A network interface 814 is also electrically connected to hardware processor 802 via bus 818. Network interface 814 is connected to a network 816, so that hardware processor 802 and computer-readable storage medium 804 are capable of connecting to external elements via network 816. Hardware processor 802 is configured to execute computer program code 806 encoded in computer-readable storage medium 804 in order to cause the EPC system 800 to be usable for performing a portion or all of the noted processes and/or methods. In one or more embodiments, hardware processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, computer-readable storage medium 804 stores computer program code 806 configured to cause the EPC system 800 (where such execution represents (at least in part) the EPC tool) to be usable for performing a portion or all of the noted processes and/or methods. In one or more embodiments, computer-readable storage medium 804 also stores information which facilitates performing a portion or all of the noted processes and/or methods. In one or more embodiments, computer-readable storage medium 804 stores process control data 808 including, in some embodiments, control algorithms, process variables and constants, target ranges, set points, programming control data, and code for enabling statistical process control (SPC) and/or model predictive control (MPC) based control of the various processes.

EPC system 800 includes I/O interface 812. I/O interface 812 is coupled to external circuitry. In one or more embodiments, I/O interface 812 includes a keyboard, keypad, mouse, trackball, trackpad, touchscreen, and/or cursor direction keys for communicating information and commands to hardware processor 802.

EPC system 800 also includes network interface 814 coupled to hardware processor 802. Network interface 814 allows EPC system 800 to communicate with network 816, to which one or more other computer systems are connected. Network interface 814 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EPC systems 800.

EPC system 800 is configured to send information to and receive information from fabrication tools 820 that include one or more of ion implant tools, etching tools, deposition tools, coating tools, rinsing tools, cleaning tools, chemical-mechanical planarizing (CMP) tools, testing tools, inspection tools, transport system tools, and thermal processing tools that will perform a predetermined series of manufacturing operations to produce the desired integrated circuit devices. The information includes one or more of operational data, parametric data, test data, and functional data used for controlling, monitoring, and/or evaluating the execution, progress, and/or completion of the specific manufacturing process. The process tool information is stored in and/or retrieved from computer-readable storage medium 804.

EPC system 800 is configured to receive information through I/O interface 812. The information received through I/O interface 812 includes one or more of instructions, data, programming data, design rules that specify, e.g., layer thicknesses, spacing distances, structure and layer resistivity, and feature sizes, process performance histories, target ranges, set points, and/or other parameters for processing by hardware processor 802. The information is transferred to hardware processor 802 via bus 818. EPC system 800 is configured to receive information related to a user interface (UI) through I/O interface 812. The information is stored in computer-readable medium 804 as user interface (UI) 810.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EPC tool. In some embodiments, a portion or all of the noted processes and/or methods is implemented as a software application that is used by EPC system 800.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

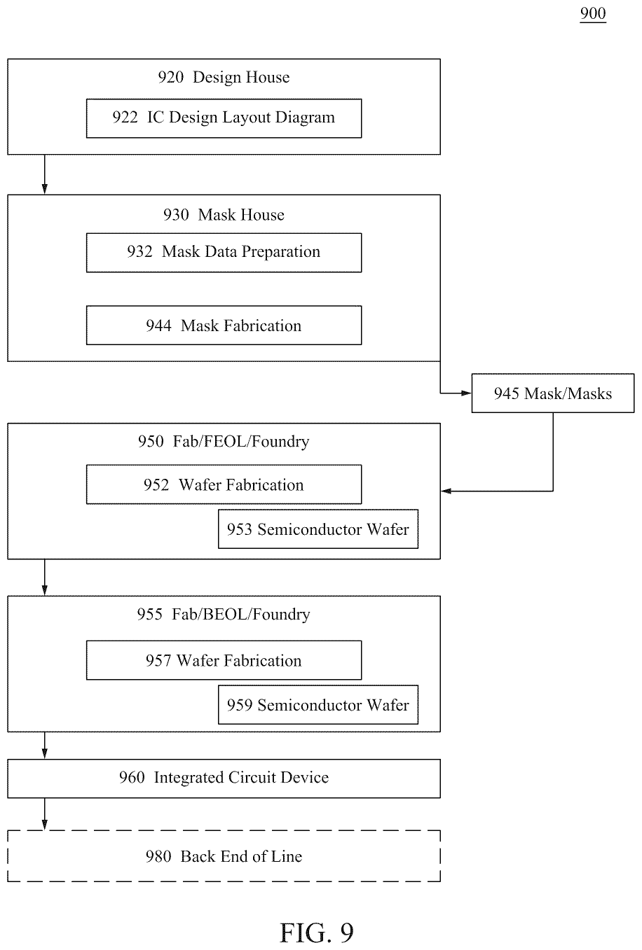

FIG. 9 is a block diagram of an integrated circuit (IC) manufacturing system 900, and an IC manufacturing flow associated therewith, in accordance with some embodiments for manufacturing IC devices that incorporate the improved control over the SSD and EPI profile. In some embodiments, based on a layout diagram, at least one of (A) one or more semiconductor masks or (B) at least one component in a layer of a semiconductor integrated circuit is fabricated using manufacturing system 900.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. Once the manufacturing process has been completed to form a plurality of IC devices on a wafer, the wafer is optionally sent to backend or back end of line (BEOL) 980 for, depending on the device, programming, electrical testing, and packaging in order to obtain the final IC device products. The entities in manufacturing system 900 are connected by a communications network. In some embodiments, the communications network is a single network. In some embodiments, the communications network is a variety of different networks, such as an intranet and the Internet.

The communications network includes wired and/or wireless communication channels. Each entity interacts with one or more of the other entities and provides services to and/or receives services from one or more of the other entities. In some embodiments, two or more of design house 920, mask house 930, and IC Fab 950 is owned by a single larger company. In some embodiments, two or more of design house 920, mask house 930, and IC Fab 950 coexist in a common facility and use common resources.

Design house (or design team) 920 generates an IC design layout diagram 922. IC design layout diagram 922 includes various geometrical patterns designed for an IC device 960. The geometrical patterns correspond to patterns of metal, oxide, or semiconductor layers that make up the various components of IC device 960 to be fabricated. The various layers combine to form various IC features.

For example, a portion of IC design layout diagram 922 includes various IC features, such as an active region, gate electrode, source and drain, metal lines or vias of an intermetal interconnection, and openings for bonding pads, to be formed in a semiconductor substrate (such as a silicon wafer) and various material layers disposed on the semiconductor substrate. Design house 920 implements a proper design procedure to form IC design layout diagram 922. The design procedure includes one or more of logic design, physical design or place and route. IC design layout diagram 922 is presented in one or more data files having information of the geometrical patterns. For example, IC design layout diagram 922, in some operations, will be expressed in a GDSII file format or DFII file format.

Whereas the pattern of a modified IC design layout diagram is adjusted by an appropriate method in order to, for example, reduce parasitic capacitance of the integrated circuit as compared to an unmodified IC design layout diagram, the modified IC design layout diagram reflects the results of changing positions of conductive line in the layout diagram, and, in some embodiments, inserting to the IC design layout diagram, features associated with capacitive isolation structures to further reduce parasitic capacitance, as compared to IC structures having the modified IC design layout diagram without features for forming capacitive isolation structures located therein.

Mask house 930 includes mask data preparation 932 and mask fabrication 944. Mask house 930 uses IC design layout diagram 922 to manufacture one or more masks 945 to be used for fabricating the various layers of IC device 960 according to IC design layout diagram 922. Mask house 930 performs mask data preparation 932, where IC design layout diagram 922 is translated into a representative data file (“RDF”). Mask data preparation 932 provides the RDF to mask fabrication 944. Mask fabrication 944 includes a mask writer. A mask writer converts the RDF to an image on a substrate, such as a mask (reticle) 945 or a semiconductor wafer 953. The IC design layout diagram 922 is manipulated by mask data preparation 932 to comply with particular characteristics of the mask writer and/or requirements of IC Fab 950. In FIG. 9, mask data preparation 932 and mask fabrication 944 are illustrated as separate elements. In some embodiments, mask data preparation 932 and mask fabrication 944 are collectively referred to as mask data preparation.

In some embodiments, mask data preparation 932 includes optical proximity correction (OPC) which uses lithography enhancement techniques to compensate for image errors, such as those that are known to arise from diffraction, interference, other process effects and the like. OPC adjusts IC design layout diagram 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for limitations during mask fabrication 944, which may undo part of the modifications performed by OPC in order to meet mask creation rules.

In some embodiments, mask data preparation 932 includes lithography process checking (LPC) that simulates processing that will be implemented by IC Fab 950 to fabricate IC device 960. LPC simulates this processing based on IC design layout diagram 922 to create a simulated manufactured device, such as IC device 960. In some embodiments, the processing parameters in LPC simulation will include parameters associated with various processes of the IC manufacturing cycle, parameters associated with tools used for manufacturing the IC, and/or other aspects of the manufacturing process. LPC accounts for various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 922.

It should be understood that the above description of mask data preparation 932 has been simplified for the purposes of clarity. In some embodiments, mask data preparation 932 includes additional features such as a logic operation (LOP) to modify the IC design layout diagram 922 according to manufacturing rules. Additionally, the processes applied to IC design layout diagram 922 during mask data preparation 932 may be executed in a variety of different orders.

After mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Mask 945 will be formed using a process selected from various available technologies. In some embodiments, mask 945 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask.

In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask will be attenuated PSM or alternating PSM. The mask(s) generated by mask fabrication 944 is used in a variety of processes. For example, such a mask(s) is used in an ion implantation process to form various doped regions in semiconductor wafer 953, in an etching process to form various etching regions in semiconductor wafer 953, and/or in other suitable processes.

IC Fab 950 includes wafer fabrication 952. IC Fab 950 is an IC fabrication business that includes one or more manufacturing facilities for the fabrication of a variety of different IC products. In some embodiments, IC Fab 950 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

Wafer fabrication 952 includes forming a patterned layer of mask material formed on a semiconductor substrate is made of a mask material that includes one or more layers of photoresist, polyimide, silicon oxide, silicon nitride (e.g., Si₃N₄, SiON, SiC, SiOC), or combinations thereof. In some embodiments, masks 945 include a single layer of mask material. In some embodiments, a mask 945 includes multiple layers of mask materials.

In some embodiments IC Fab 955 includes wafer fabrication 957. IC Fab 955 is an IC fabrication business that includes one or more manufacturing facilities for the fabrication of a variety of different IC products. In some embodiments, IC Fab 955 is a manufacturing facility provide the back end fabrication for the interconnection and packaging of the IC products (back-end-of-line (BEOL) fabrication) to add one or more metallization layers to semiconductor wafer 959, and a third manufacturing facility (not shown) may provide other services for the foundry business such as packaging and labelling.

In some embodiments, the mask material is patterned by exposure to an illumination source. In some embodiments, the illumination source is an electron beam source. In some embodiments, the illumination source is a lamp that emits light. In some embodiments, the light is ultraviolet light. In some embodiments, the light is visible light. In some embodiments, the light is infrared light. In some embodiments, the illumination source emits a combination of different (UV, visible, and/or infrared) light.

In some embodiments, etching processes include presenting the exposed structures in the functional area(s) to an oxygen-containing atmosphere to oxidize an outer portion of the exposed structures, followed by a chemical trimming process such as plasma-etching or liquid chemical etching, as described above, to remove the oxidized material and leave behind a modified structure. In some embodiments, oxidation followed by chemical trimming is performed to provide greater dimensional selectivity to the exposed material and to reduce a likelihood of accidental material removal during a manufacturing process. In some embodiments, the exposed structures may include the fin structures of Fin Field Effect Transistors (FinFET) with the fins being embedded in a dielectric support medium covering the sides of the fins. In some embodiments, the exposed portions of the fins of the functional area are top surfaces and sides of the fins that are above a top surface of the dielectric support medium, where the top surface of the dielectric support medium has been recessed to a level below the top surface of the fins, but still covering a lower portion of the sides of the fins.

Subsequent to mask patterning operations, areas not covered by the mask are etched to modify a dimension of one or more structures within the exposed area(s). In some embodiments, the etching is performed using plasma etching, reactive ion etching (RIE), or a liquid chemical etch solution, according to some embodiments. The chemistry of the liquid chemical etch solution includes one or more of etchants such as citric acid (C₆H₈O₇), hydrogen peroxide (H₂O₂), nitric acid (HNO₃), sulfuric acid (H₂SO₄), hydrochloric acid (HCl), acetic acid (CH₃CO₂H), hydrofluoric acid (HF), buffered hydrofluoric acid (BHF), phosphoric acid (H₃PO₄), ammonium fluoride (NH₄F) potassium hydroxide (KOH), ethylenediamine pyrocatechol (EDP), TMAH (tetramethylammonium hydroxide), or a combination thereof.

In some embodiments, the etching process is a dry-etch or plasma etch process. Plasma etching of a substrate material is performed using halogen-containing reactive gasses excited by an electromagnetic field to dissociate into ions. Reactive or etchant gases include, for example, CF₄, SF₆, NF₃, Cl₂, CCl₂F₂, SiCl₄, BCl₂, or a combination thereof, although other semiconductor-material etchant gases are also envisioned within the scope of the present disclosure. Ions are accelerated to strike exposed material by alternating electromagnetic fields or by fixed bias according to methods of plasma etching that are known in the art.

In some embodiments, molecular level processing technologies that share the self-limiting surface reaction characteristics utilized in ALD including, for example, Molecular Layer Deposition (MLD) and Self-Assembled Monolayers (SAM). MLD utilizes successive precursor-surface reactions in which a precursor is introduced into a reaction zone above the wafer surface. The precursor adsorbs to the wafer surface where it is confined by physisorption. The precursor then undergoes a quick chemisorption reaction with a number of active surface sites, leading to the self-limiting formation of molecular attachments in specific assemblies or regularly recurring structures. These MLD structures will be formed successfully using lower process temperatures than some traditional deposition techniques.

SAM is a deposition technique that involves the spontaneous adherence of organized organic structures on a wafer surface. This adherence involves adsorption of the organic structures from the vapor or liquid phase utilizing relatively weak interactions with the wafer surface. Initially, the structures are adsorbed on the surface by physisorption through, for instance, van der Waals forces or polar interactions. The self-assembled monolayers will then become confined to the surface by a chemisorption process. In some embodiments, the ability of SAM to grow layers as thin as a single molecule through chemisorption-driven interactions with the wafer surface(s) will be particularly useful in forming thin films including, for example, “near-zero-thickness” activation or barrier layers. SAM will also be particularly useful in area-selective deposition (ASD) (or area-specific deposition) using molecules that exhibit preferential reactions with specific segments of the underlying wafer surface in order to facilitate or obstruct subsequent material growth in the targeted areas. In some embodiments, SAM is used to form a foundation or blueprint region for subsequent area-selective ALD (AS-ALD) or area-selective CVD (AS-CVD).

The ALD, MLD, and SAM processes represent viable options for manufacturing thin layers (in some embodiments, the manufactured layers are only few atoms thick) that exhibit sufficient uniformity, conformality, and/or purity for the intended IC device application. By delivering the constituents of the material systems being manufactured both individually and sequentially into the processing environment, these processes and the precise control of the resulting surface chemical reactions allow for excellent control of processing parameters and the target composition and performance of the resulting film(s).

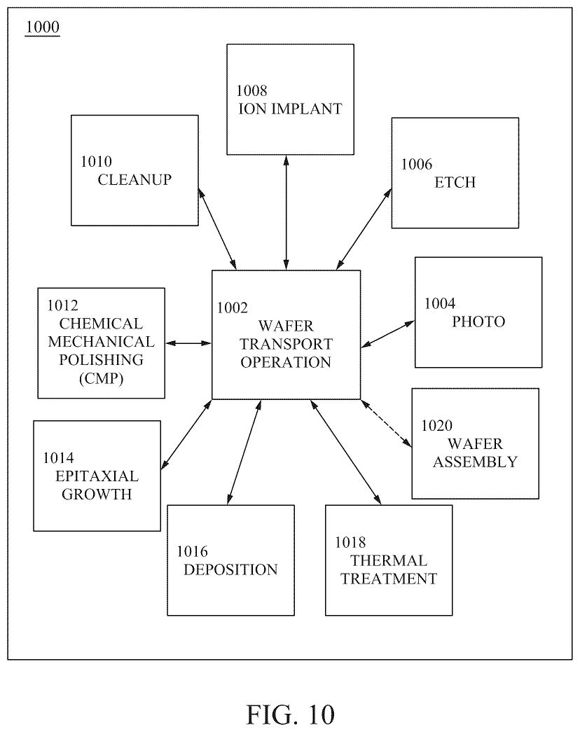

FIG. 10 is a schematic diagram of various processing departments defined within a Fab/Front End/Foundry for manufacturing IC devices according to some embodiments. The processing departments utilized in both front end of line (FEOL) and back end of line (BEOL) IC device manufacturing typically include a wafer transport operation 1002 for moving the wafers between the various processing departments. In some embodiments, the wafer transport operation will be integrated with an electronic process control (EPC) system according to FIG. 5 and utilized for providing process control operations, ensuring that the wafers being both processed in a timely manner and sequentially delivered to the appropriate processing departments as determined by the process flow. In some embodiments, the EPC system will also provide control and/or quality assurance and parametric data for the proper operation of the defined processing equipment. Interconnected by the wafer transport operation 1002 will be the various processing departments providing, for example, photolithographic operations 1004, etch operations 1006, ion implant operations 1008, clean-up/strip operations 1010, chemical mechanical polishing (CMP) operations 1012, epitaxial growth operations 1014, deposition operations 1016, thermal treatments 1018, and, in some embodiments, wafer assembly 1020 during which two or more substrates are joined to form a final device substrate structure.

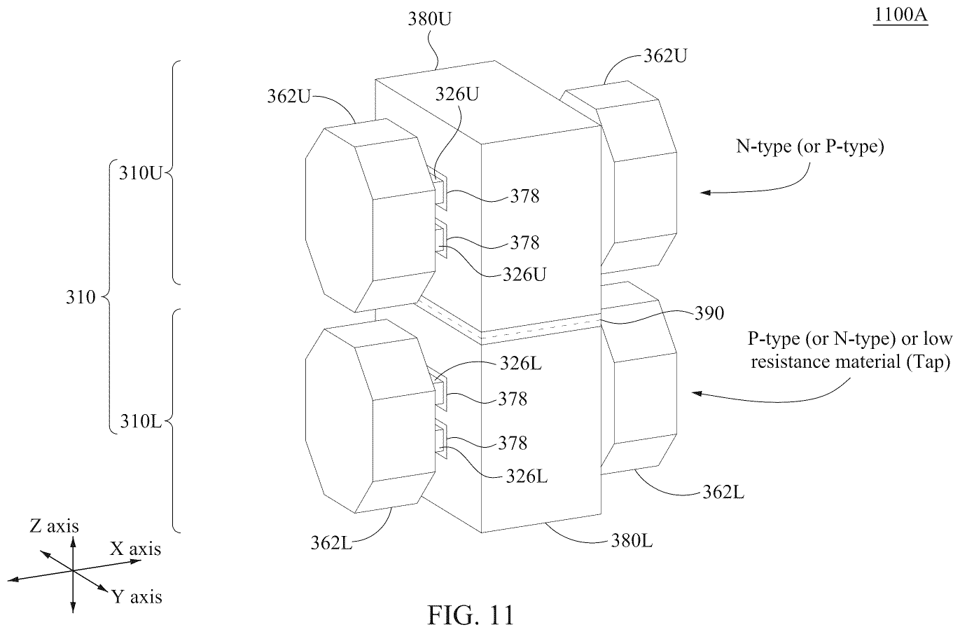

FIG. 11 is a schematic perspective view of a stack of semiconductor devices, or a device stack, 1100A, in accordance with some embodiments. The device stack 1100A comprises a stacked structure 310 of a lower semiconductor device 310L and an upper semiconductor device 310U. The lower semiconductor device 310L is over a substrate. For simplicity, the substrate is not illustrated in FIG. 11. The upper semiconductor device 310U is physically stacked over the lower semiconductor device 310L in a thickness direction of the substrate. The thickness direction is designated as a Z axis in FIG. 11. Both upper semiconductor device 310U and lower semiconductor device 310L are of a same conductivity type. Conductivity type is sometimes referred to as semiconductor type. Examples of conductivity type include N-type and P-type. In at least one embodiment, both upper semiconductor device 310U and lower semiconductor device 310L are N-type semiconductor devices, and the stacked structure 310 is referred to as an N-on-N structure. In one or more embodiments both upper semiconductor device 310U and lower semiconductor device 310L are P-type semiconductor devices, and the stacked structure 310 is referred to as a P-on-P structure. In one or more embodiments the upper semiconductor device 310U is an N-type semiconductor device and the lower semiconductor device 310L is a P-type semiconductor device, and the stacked structure 310 is referred to as a N-on-P structure. In one or more embodiments the upper semiconductor device 310U is a P-type semiconductor device and the lower semiconductor device 310L is an N-type semiconductor device, and the stacked structure 310 is referred to as a P-on-N structure. In one or more embodiments the upper semiconductor device 310U is an N-type or P-type semiconductor device and the lower semiconductor device 310L is a low resistance material, and the stacked structure 310 is referred to as a N (or P)-on-Tap structure. Examples of semiconductor devices include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

In the example configuration in FIG. 11, the upper semiconductor device 310U and lower semiconductor device 310L are nanosheet FETs. Other semiconductor device configurations are within the scopes of various embodiments. In some embodiments, the upper semiconductor device 310U and lower semiconductor device 310L have different semiconductor device configurations. For example, in some embodiments the lower semiconductor device 310L is a planar MOS transistor whereas the upper semiconductor device 310U is a nanosheet FET.

The upper semiconductor device 310U comprises a gate 380U, and source/drains 362U on opposite sides of the gate 380U along an X-axis. The gate 380U extends, or is elongated, along a Y-axis. The X-axis, Y-axis, Z-axis are mutually transverse to each other. In some embodiments, the X-axis, Y-axis, Z-axis are mutually perpendicular to each other. The upper semiconductor device 310U further comprises a channel region configured by nanosheets 326U which extend along the X-axis and connect the source/drains 362U. In the example configuration in FIG. 11, the upper semiconductor device 310U comprises two nanosheets 326U. Other numbers of nanosheets per transistor are within the scopes of various embodiments. The upper semiconductor device 310U comprises a gate dielectric layer 378 extending around each of the nanosheets 326U, and electrically isolating the gate 380U from the nanosheets 326U. The gate 380U extends around the gate dielectric layer 378 and nanosheets 326U in a configuration referred to as a gate-all-around (GAA) configuration. Other gate configurations are within the scopes of various embodiments.

The lower semiconductor device 310L comprises a gate 380L, source/drains 362L, a channel region configured by nanosheets 326L, and a gate dielectric layer 378 extending around each of the nanosheets 326L. The gate 380L, source/drains 362L, and nanosheets 326L correspond to the gate 380U, source/drains 362U, and nanosheets 326U. The gate 380U, source/drains 362U, and nanosheets 326U correspondingly overlap the gate 380L, source/drains 362L, and nanosheets 326L along the Z axis. In the example configuration in FIG. 11, the source/drains 362U, 362L are epitaxy structures of the same conductivity type. For example, all source/drains 362U, 362L are P-type epitaxy structures, or all source/drains 362U, 362L are N-type epitaxy structures.

The stacked structure 310 further comprises an intermediate layer 390 between the gate 380U and gate 380L. In some embodiments, the intermediate layer 390 is a dielectric layer electrically isolating the gate 380U from the gate 380L, in a configuration referred to as an isolated gate configuration in which the gate 380U and gate 380L are controllable independently from each other. In at least one embodiment, the gate 380U and the gate 380L in an isolated gate configuration are still electrically coupled to each other by a conductor, e.g., a gate local interconnect (MGLI). In some embodiments, the intermediate layer 390 is a conductive layer electrically coupling the gate 380U to the gate 380L, in a configuration referred to as a connected gate configuration in which the electrically coupled gate 380U and gate 380L form a common gate for both upper semiconductor device 310U and lower semiconductor device 310L. In a connected gate configuration in accordance with some embodiments, the conductive intermediate layer 390 is formed integrally, and/or simultaneously, with the gate 380U and gate 380L in a single GAA structure.

As can be seen from FIG. 11, in one or more embodiments, the stacking of the upper semiconductor device 310U over the lower semiconductor device 310L saves about 50% of the required chip area, compared to other approaches without stacking of semiconductor devices. Further, compared to CFET devices where semiconductor devices of different conductivity types are stacked one over another, device stacks in accordance with some embodiments are advantageous in IC regions or circuits or applications where multiple semiconductor devices of one conductivity type, e.g., multiple P-type devices or multiple N-type devices, are required or included, whereas semiconductor devices of the other conductivity type are not required or included. In some embodiments, it is possible to manufacturing an IC device comprising multiple device stacks by CFET processes, with little or no changes to the manufacturing processes.

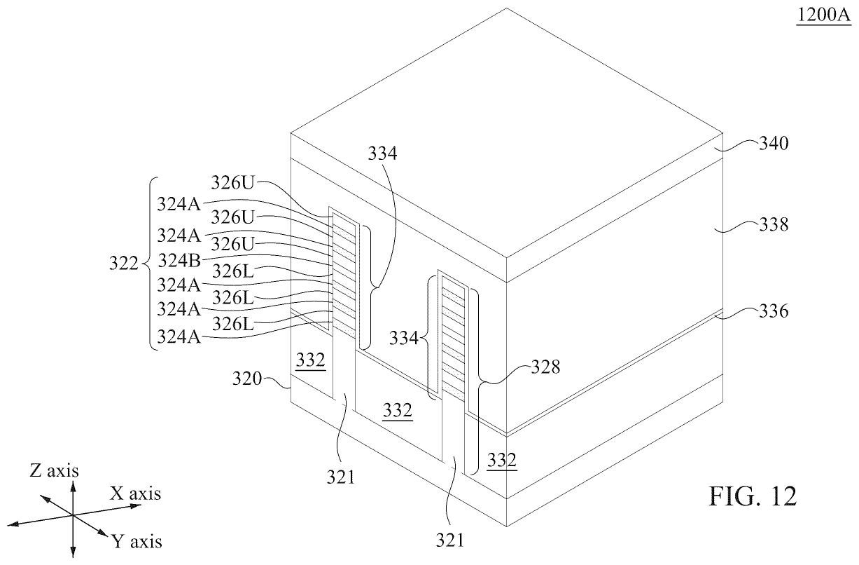

FIG. 12 is a schematic perspective view of an IC device 300A in accordance with some embodiments. The IC device 300A comprises a plurality of device stacks formed on a substrate 320. In some embodiments, the substrate 320 is a semiconductor substrate. In some embodiments, the substrate 320 includes a single crystalline semiconductor layer on at least the surface of the substrate 320. Example materials of the substrate 320 include, but are not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 320 is a silicon-on-insulator (SOI) substrate, which includes an insulating layer disposed between two silicon layers. In at least one embodiment, the insulating layer is an oxide layer.

A multilayer structure 322 is formed over the substrate 320. In FIG. 12, the multilayer structure 322 is illustrated in a state after formation of fins, as described herein. The multilayer structure 322 comprises alternatingly arranged first semiconductor layers 324A, 324B and second semiconductor layers 326U, 326L. The second semiconductor layers 326U, 326L correspond to the nanosheets described with respect to FIG. 11 and are referred to herein by the same reference numerals of the nanosheets, for simplicity. The first semiconductor layers 324A, 324B and the second semiconductor layers 326U, 326L comprise semiconductor materials having different etch selectivity and/or oxidation rates. For example, in some embodiments the first semiconductor layers 324A, 324B comprise SiGe, and the second semiconductor layers 326U, 326L comprise Si. In some embodiments, the first and second semiconductor layers 324A, 324B, 326U, 326L are formed by a deposition process, such as epitaxy. For example, epitaxial growth of the layers of the multilayer structure 322 is performed by a molecular beam epitaxy (MBE) process, a metalorganic chemical vapor deposition (MOCVD) process, and/or other suitable epitaxial growth processes.

Subsequent to the formation of the multilayer structure 322, fins 328 are formed. Each fin 328 comprises a substrate portion 321 of the substrate 320, and a portion 334 of the multilayer structure 322. The portion 334 of the multilayer structure 322 is sometimes referred to as a stack of semiconductor layers 334. In some embodiments, the fins 328 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 328 by etching the multilayer structure 322 and the substrate 320. Example etch processes include, but are not limited to, dry etch, wet etch, reactive ion etch (RIE), and/or other suitable processes. In FIG. 12, two fins 328 are illustrated; however, the number of the fins is not limited to two. The fins 328 extend, or are elongated, along the X-axis.

In some embodiments, a shallow trench isolation (STI) 332 of an insulating material is formed over the substrate 320 and in trenches (not numbered) between the fins 328. For example, the insulating material is deposited over the substrate 320 and the fins 328. Example insulating materials of the STI 332 include, but are not limited to, silicon oxide, fluorine-doped silicate glass (FSG), silicon nitride, silicon oxynitride (SiON), silicon oxycarbonitride (SiOCN), silicon carbonitride (SiCN), a low-k dielectric material, or the like. The deposition of the insulating material includes a suitable method, such as low-pressure chemical vapor deposition (LPCVD), plasma enhanced CVD (PECVD) or flowable CVD (FCVD). Then, a planarization operation, such as a chemical mechanical polishing (CMP) process and/or an etch-back process, is performed such that the tops of the fins 328 are exposed from the insulating material. A portion of the insulating material between adjacent fins 328 is removed. The remaining portion of the insulating material configures the STI 332. The partial removal of the insulating material includes dry etch, wet etch, or the like.

In some embodiments, a sacrificial gate dielectric layer 336, a sacrificial gate electrode layer 338, and a mask structure 340 are deposited over the STI 332 and fins 328. In some embodiments, the sacrificial gate dielectric layer 336 comprises one or more layers of dielectric material, such as SiO2, SiN, a high-k dielectric material, and/or other suitable dielectric material. In some embodiments, the sacrificial gate dielectric layer 336 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 338 comprises polycrystalline silicon (polysilicon). In some embodiments, the mask structure 340 comprises a multilayer structure. In some embodiments, the sacrificial gate electrode layer 338 and the mask structure 340 are formed by one or more processes such as layer deposition, for example, CVD (including both LPCVD and PECVD), PVD, ALD, thermal oxidation, e-beam evaporation, or other suitable deposition techniques to obtain structure 1200A is obtained.

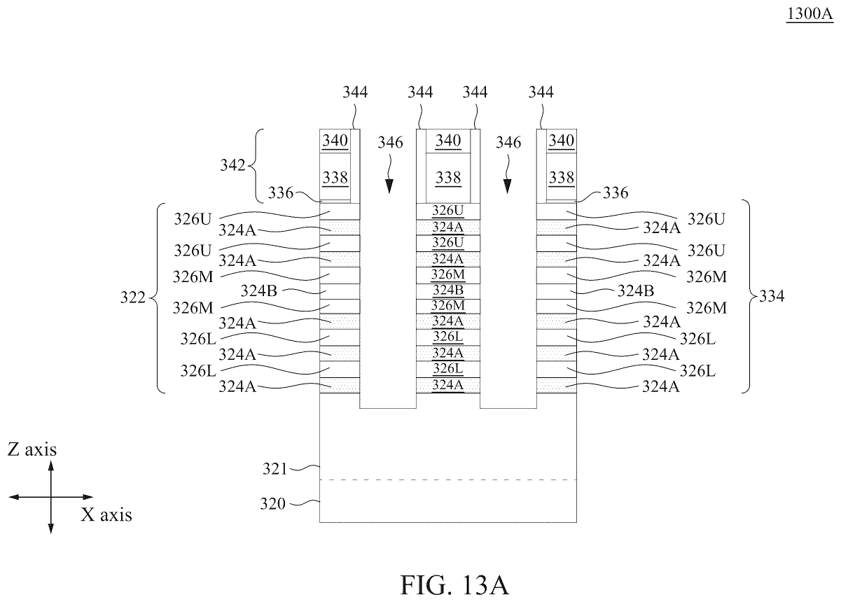

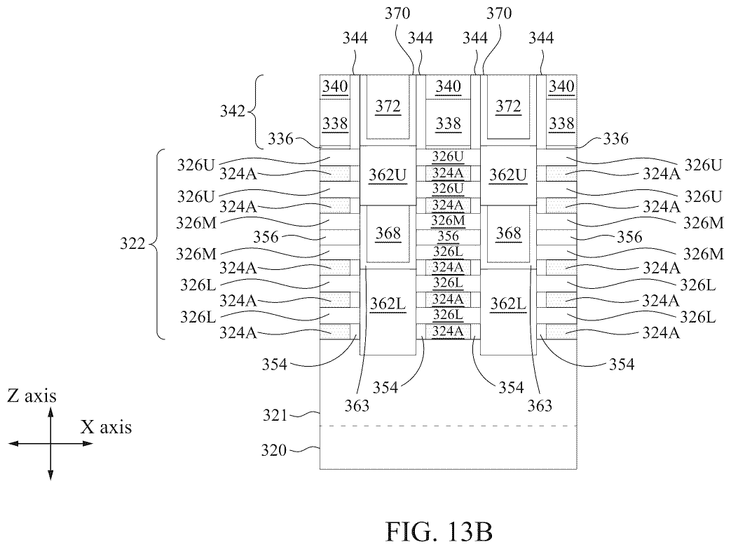

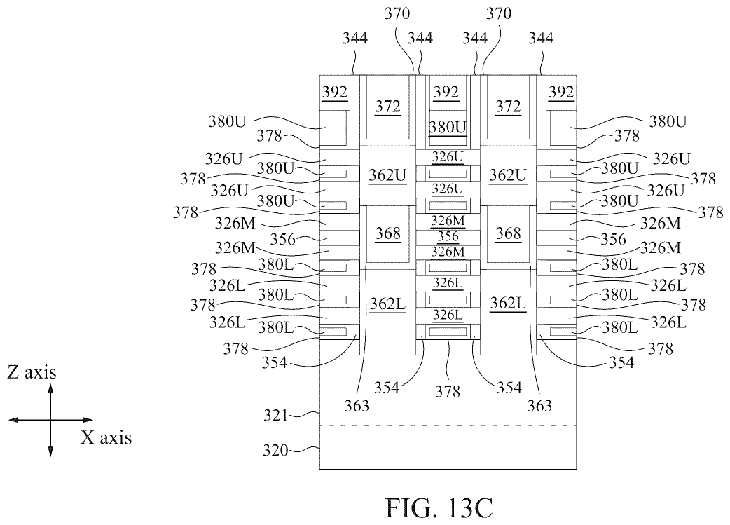

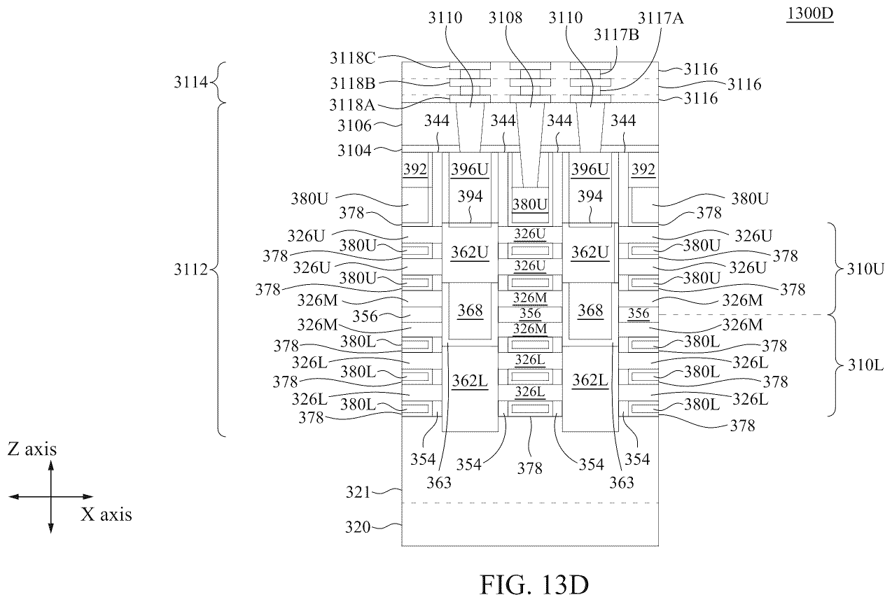

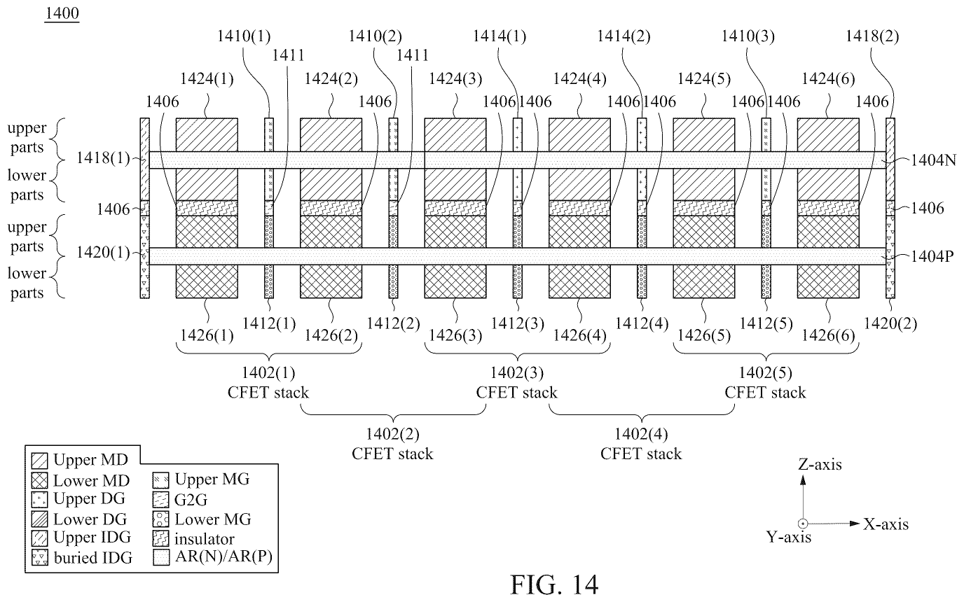

Referring to FIG. 13A, sacrificial gate stacks 342 are formed by one or more pattern and/or etch processes performed on the deposited sacrificial gate dielectric layer 336, sacrificial gate electrode layer 338, and mask structure 340 of the structure 300A. An example pattern process comprises a lithography process. An example etch process comprises dry etch (e.g., RIE), wet etch, other etch methods, and/or combinations thereof. Each sacrificial gate stack 342 comprises a portion of each of the sacrificial gate dielectric layer 336, sacrificial gate electrode layer 338, and mask structure 340. The sacrificial gate stacks 342 extend, or are elongated, along the Y axis. In FIG. 13A, three sacrificial gate stacks 342 are illustrated; however, the number of the sacrificial gate stacks 342 is not limited to two.

Spacers 344 are formed on sidewalls of the sacrificial gate stacks 342. For example, the spacers 344 are formed by first depositing a conformal layer that is subsequently etched back to form the spacers 344. The spacers 344 comprises a dielectric material, such as silicon oxide, silicon nitride, silicon carbide, silicon oxynitride, SiCN, silicon oxycarbide, SiOCN, and/or combinations thereof. In some embodiments, the spacers 344 comprise multiple layers.

Exposed portions of the stacks of semiconductor layers 334 of the fins 328 not covered by the sacrificial gate stacks 342 and the spacers 344 are selectively removed, e.g., by one or more suitable etch processes, such as dry etch, wet etch, or a combination thereof, to form trenches 346. In FIG. 13A, a lower most one of the second semiconductor layers 326U and an uppermost one of the second semiconductor layers 326L are designated as middle second semiconductor layers 326M which sandwich therebetween a middle first semiconductor layer 324B. The middle second semiconductor layers 326M and the middle first semiconductor layer 324B are not configured to form channel regions of the upper semiconductor device 310U and lower semiconductor device 310L. Edge portions of the first semiconductor layers 324A, 324B and second semiconductor layers 326U, 326L, 326M are exposed in the trenches 346. The trenches 346 also expose portions of the substrate portion 321 and obtain the structure 1300A.

Referring to FIG. 13B, the exposed edge portions of the first semiconductor layers 324A are removed. In some embodiments, the removal comprises a selective wet etch process. The selective wet etch process further completely (or substantially completely) removes the first semiconductor layer 324B in the middle of the stack of semiconductor layers 334. For example, in embodiments where the first semiconductor layers 324A, 324B comprise SiGe, and the second semiconductor layers 326U, 326L, 326M comprise Si, a selective wet etch is configured to etch the first semiconductor layer 324B at a highest etch rate, the first semiconductor layers 324A at a second highest etch rate, and the second semiconductor layers 326U, 326L, 326M at a slowest etch rate. As a result, the exposed edge portions of the first semiconductor layers 324A and an entirety (or substantially an entirety) of the first semiconductor layer 324B are removed, whereas the second semiconductor layers 326U, 326L, 326M are substantially unchanged.

A dielectric material is deposited over and into the spaces created by the removal of the first semiconductor layer 324B and the partial removal of the edge portions of the first semiconductor layers 324A. The dielectric material filling in the spaces created by the partial removal of the edge portions of the first semiconductor layers 324A configures inner spacers 354. The dielectric material filling in the space created by the removal of the first semiconductor layer 324B configures an inner isolation structure 356. Examples of the dielectric material forming the inner spacers 354 and inner isolation structure 356 include, but are not limited to, a low-k dielectric material, such as SiO2, SiN, SiCN, SiOC, or SiOCN, or a high-k dielectric material, such as HfO2, ZrOx, ZrAlOx, HfAlOx, HfSiOx, AlOx, or other suitable dielectric material. In some embodiments, the inner spacers 354 and inner isolation structure 356 comprise different dielectric materials. In an example process, the inner spacers 354 and inner isolation structure 356 are formed by depositing a conformal layer of the dielectric material, using a conformal deposition process, such as ALD, followed by an anisotropic etching to remove portions of the conformal layer other than the inner spacers 354 and inner isolation structure 356.

Source/drain 362L are formed over, and in contact with, the exposed portions of the substrate portions 321, and exposed edge portions of the second semiconductor layers 326L. In the example configuration in FIG. 13B, the source/drains 362L comprise epitaxy structures and are sometimes referred to as source/drain epitaxy structures 362L. In some embodiments, the source/drain epitaxy structures 362L comprise one or more layers of Si, SiP, SiC and SiCP to configure an N-type bottom semiconductor device. In some embodiments, the source/drain epitaxy structures 362L comprise one or more layers of Si, SiGe, Ge to configure a P-type bottom semiconductor device. Example epitaxial growth processes for growing the source/drain epitaxy structures 362L include, but are not limited to, CVD, ALD, MBE. In some embodiments, source/drain epitaxy structures 362L are grown to a height above the uppermost second semiconductor layer 326L, and then top portions of the source/drain epitaxy structures 362L are partially removed, e.g., by a dry etch or wet etch, so that upper surfaces of the remaining source/drain epitaxy structures 362L are at a level of the uppermost first semiconductor layer 324A immediately under the lower middle second semiconductor layer 326M, as illustrated in FIG. 13B.

A liner 363 is formed at least over the upper surfaces of the source/drain epitaxy structures 362L, and exposed side faces of the middle second semiconductor layers 326M, inner isolation structure 356. In some embodiments, the liner 363 comprises Si. In an example process, the liner 363 is a conformal layer formed by a conformal process, such as an ALD process.

A dielectric material 368 is formed over the liner 363 and over the source/drain epitaxy structures 362L. In some embodiments, the dielectric material 368 comprises the same material as the STI 332 and/or is formed by the same method as the STI 332. The liner 363 and dielectric material 368 are removed outside the trenches 346, and partially removed inside the trenches 346, e.g., by a dry etch or wet etch. As a result, upper surfaces of the liner 363 and dielectric material 368 are at a level of the lowermost first semiconductor layer 324A immediately above the upper middle second semiconductor layer 326M, as illustrated in FIG. 13B. The liner 363 and dielectric material 368 configure an isolation structure between the source/drain 362L and source/drains 362U to be subsequently formed thereover.

Source/drain 362U are formed over, and in contact with, the upper surfaces of the liner 363 and dielectric material 368, and exposed edge portions of the second semiconductor layers 326U. In the example configuration in FIG. 13B, the source/drains 362U comprise epitaxy structures and are sometimes referred to as source/drain epitaxy structures 362U. The source/drain epitaxy structures 362U are of the same conductivity type as the source/drain epitaxy structures 362L. In some embodiments, the source/drain epitaxy structures 362U comprise the same material and/or are manufactured by the same manufacturing processes as the source/drain epitaxy structures 362L. In at least one embodiment, the source/drain epitaxy structures 362U have the same configuration, e.g., the same size, shape, height, material, as the source/drain epitaxy structures 362L. In an example, where the source/drain epitaxy structures 362L comprise one or more layers of Si, SiP, SiC and SiCP to configure an N-type bottom semiconductor device, the source/drain epitaxy structures 362U comprise one or more layers of Si, SiP, SiC and SiCP to configure an N-type top semiconductor device. In another example, where the source/drain epitaxy structures 362L comprise one or more layers of Si, SiGe, Ge to configure a P-type bottom semiconductor device, the source/drain epitaxy structures 362U comprise one or more layers of Si, SiGe, Ge to configure a P-type top semiconductor device. In some embodiments, source/drain epitaxy structures 362U are grown to a height above the sacrificial gate dielectric layer 336, and then top portions of the source/drain epitaxy structures 362U are partially removed, e.g., by a dry etch or wet etch, so that upper surfaces of the remaining source/drain epitaxy structures 362U are at a level of the sacrificial gate dielectric layer 336, as illustrated in FIG. 13D. This is an example, and a height of the source/drain epitaxy structures 362U is controllable depending on application and/or process requirements.

A contact etch stop layer (CESL) 370 is formed over the source/drain epitaxy structures 362U. Example materials of the CESL 370 include, but are not limited to, silicon nitride, silicon carbon nitride, silicon oxynitride, carbon nitride, silicon oxide, silicon carbon oxide, the like, or a combination thereof. The CESL 370 is formed by CVD, PECVD, ALD, or any suitable deposition technique.

An interlayer dielectric (ILD) layer 372 is formed over the CESL 370. Example materials of the ILD layer 372 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 372 is deposited by a PECVD process or other suitable deposition technique so obtain structure 1300B.

Referring to FIG. 13C, a planarization process, such as a CMP process, is performed to remove the mask structure 340 and expose the sacrificial gate electrode layer 338. The planarization process also removes portions of the ILD layer 372 and the CESL 370.

The exposed sacrificial gate electrode layer 338 and the sacrificial gate dielectric layer 336 are removed, e.g., by one or more suitable processes, such as dry etch, wet etch, or a combination thereof.

Next, the first semiconductor layers 324A are removed, e.g., by any suitable processes, such as dry etch, wet etch, or a combination thereof. The removal of the first semiconductor layers 324A exposes the inner spacers 354 and the second semiconductor layers 326U, 326L, and creates spaces between and around exposed portions of the second semiconductor layers 326U, 326L not covered by the inner spacers 354. The exposed portions of the second semiconductor layers 326U, 326L configure the nanosheets 326U, 326L described with respect to FIG. 11. The middle second semiconductor layers 326M and inner isolation structure 356 are covered by the liner 363 and dielectric material 368 and are substantially unaffected by the removal of the first semiconductor layers 324A.

A gate dielectric layer 378 is formed over and around each of the nanosheets 326U, 326L. In some embodiments, the gate dielectric layer 378 comprises the same material as the sacrificial gate dielectric layer 336. In some embodiments, the gate dielectric layer 378 comprises a high-k dielectric material. In some embodiments, the gate dielectric layer 378 is formed by a conformal process, such as an ALD process.

A gate electrode material is formed over and around the gate dielectric layers 378, and the nanosheets 326U, 326L. The gate electrode material surrounding each of the nanosheets 326U configures the gate 380U. The gate electrode material surrounding each of the nanosheets 326L configures the gate 380L. In some embodiments, the gate electrode material comprises multiple gate electrode layers. Example gate electrode materials include, but are not limited to, polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode material comprises a P-type gate electrode layer, such as TiN, TaN, TiTaN, TiAlN, WCN, W, Ni, Co, or other suitable material, for configuring P-type top and bottom semiconductor devices. In at least one embodiment, the gate electrode material comprises an N-type gate electrode layer, such as TiAlC, TaAlC, TiSiAlC, TiC, TaSiAlC, or other suitable material, for configuring N-type top and bottom semiconductor devices. Example processes for depositing the gate electrode material include, but are not limited to, PVD, CVD, ALD, electro-plating, or other suitable methods.

In some embodiments, each of the gate 380U and gate 380L comprises a corresponding GAA structure, and the gate 380U and gate 380L are physically and electrically separated from each other by the middle second semiconductor layers 326M and inner isolation structure 356. In some embodiments, a combination of the middle second semiconductor layers 326M and inner isolation structure 356 corresponds to the intermediate layer 390 being a dielectric material in an isolated gate configuration. In at least one embodiment, the gate 380U and the gate 380L in an isolated gate configuration are still electrically coupled to each other by a conductor, e.g., an MGLI interconnect. In some embodiments, the gate 380U and gate 380L are integral parts of a GAA structure which extends around each of the nanosheets 326U, 326L, and configures a common gate for both upper semiconductor device and lower semiconductor device. The formation of the gate 380U and gate 380L completes the formation of the top semiconductor device 310U and bottom semiconductor device 310L.

An ILD layer 392 similar to the ILD layer 372 is deposited over the gate 380U, and a planarization process, such as a CMP, is performed to obtain structure 1300C.

Referring to FIG. 13D, openings are formed in the ILD layer 372 to expose the source/drain epitaxy structures 362U. A silicide layer 394 is formed over the exposed source/drain epitaxy structures 362U, and then source/drain contacts 396U are form in each opening and over the silicide layer 394. Source/drain contacts are sometimes referred to as metal-to-device (MD) contacts. Source/drain contacts of top semiconductor devices are sometimes referred to as MD contacts. Source/drain contacts of bottom semiconductor devices are sometimes referred to as BMD contacts. For simplicity, an MD contact herein refers to either an MD contact at the upper layer or a BMD contact at the lower layer, unless specified otherwise. Example materials of the source/drain contacts 396U include, but are not limited to, Ru, Mo, Co, Ni. W, Ti, Ta, Cu, Al, TiN and TaN. The source/drain contacts 396U are formed by any suitable process, such as PVD, ECP, or CVD.

Dielectric layers 3104, 3106 are deposited over the MD contacts 396U and ILD layer 392. Various vias 3108, 3110 are formed by etching via openings in the dielectric layers 3104, 3106 and ILD layer 392, and then filling the via openings with a conductive material, such as a metal. A via over and in electrical contact with an MD contact is sometimes referred to as via-to-device (VD) via. A via over and in electrical contact with a gate is sometimes referred to as via-to-gate (VG) via. In the example configuration in FIG. 13D, the via 3108 is a VG via which is over the gate 380U, and the vias 3110 are VD vias correspondingly over the MD contacts 396U. VG and VD vias for bottom semiconductor devices are sometimes correspondingly referred to as BVG and BVD vias.

In some embodiments, the formation of the VG, VD vias completes a front-end-of-line (FEOL) fabrication. A resulting FEOL structure 3112 comprising various semiconductor devices formed over a front side (or upper side) of the substrate 320 and the corresponding MD contacts, VG and VD vias is obtained. The FEOL fabrication is followed by a Back End of Line (BEOL) fabrication to provide routing for the semiconductor devices.

The BEOL fabrication comprises forming a redistribution structure 3114 over the VD, VG vias 3108, 3110. The redistribution structure 3114 comprises a plurality of metal layers 3118A-C and via layers 3117A-B sequentially and alternatingly formed over the VD, VG vias 3108, 3110. The redistribution structure 3114 further comprises various interlayer dielectric (ILD) layers 3116 in which the metal layers and via layers are embedded. The metal layers and via layers of the redistribution structure 3114 are configured to electrically couple various semiconductor devices, or circuits of the IC device with each other, and/or with external circuitry. In the redistribution structure 3114, the lowermost metal layer 3118A immediately over and in electrical contact with the VD, VG vias 3108, 3110 is an M0 (metal-zero) layer, a next metal layer 3118B immediately over the M0 layer is an M1 layer, a next metal layer 3118C immediately over the M1 layer is an M2 layer, or the like. Conductive patterns in the M0 layer are referred to as M0 conductive patterns, conductive patterns in the M1 layer are referred to as M1 conductive patterns, or the like. A via layer Vn is arranged between and electrically couple the Mn layer and the Mn+1 layer, where n is an integer from zero and up. For example, the via layer 3117A is a via-zero (V0) layer which is the lowermost via layer arranged between and electrically couple the M0 layer 3118A and the M1 layer 3118B. The next via layer 3117B is a V1 layer which is the via layer arranged between and electrically couple the M1 layer 3118B and the M2 layer 3118C. Vias in the V0 layer are referred to as V0 vias, vias in the V1 layer are referred to as V1 vias, or the like. For simplicity, metal layers and via layers in the redistribution structure 3114 are not fully illustrated in FIG. 13D. The redistribution structure 3114 and interconnects therein are formed over the front side of the substrate 320 and are sometimes referred to as the front side redistribution structure and front side interconnects to obtain the integrated circuit 1300D as shown in FIG. 13D.

In some embodiments, the BEOL fabrication of the IC device further comprises forming a back side redistribution structure (not shown) and corresponding back side interconnects on the back side (e.g., the lower side in FIG. 1C) of the substrate 320. An example back side redistribution structure is described with respect to FIGS. 2C, 2D. In an example manufacturing process, the structure 1300D is flipped over and temporarily bonded to a carrier (not shown). Wafer thinning is performed from the back side (now facing upward) to remove a portion of the substrate 320. For example, as illustrated in FIG. 13D, a substrate portion 3130 of the substrate 320 remains as a result of the wafer thinning on the back side. In some embodiments, the wafer thinning process includes a grinding operation, a polishing operation (such as, chemical mechanical polishing (CMP)), or the like. In at least one embodiment, the substrate 320 is completely removed, and a new substrate (not shown), e.g., an insulation substrate, is formed over the lower semiconductor device 310L.

A back side redistribution structure is formed, in a manner similar to the redistribution structure 3114, over the remaining substrate portion 3130 or the new substrate. The back side redistribution structure comprises various back side metal layers and various back side via layers arranged alternatingly in the thickness direction, i.e., along the Z axis. The back side redistribution structure further comprises various interlayer dielectric (ILD) layers in which the back side metal layers and back side via layers are embedded. The back side metal layer immediately adjacent the lower semiconductor device 310L is a back side M0 (BM0) layer, a next back side metal layer is a back side M1 (BM1) layer, or the like. A back side via layer BVn is arranged between and electrically couples the BMn layer and the BMn+1 layer, where n is an integer from zero and up. For example, a via layer BV0 is the back side via layer arranged between and electrically couples the BM0 layer and the BM1 layer. Other back side via layers are BV1, BV2, or the like. Conductive patterns in the BM0 layer are referred to as BM0 conductive patterns, conductive patterns in the BM1 layer are referred to as BM1 conductive patterns, or the like. Vias in the BV0 layer are referred to as BV0 vias, vias in the BV1 layer are referred to as BV1 vias, or the like.

In at least one embodiment, one or more advantages described herein are achievable by IC devices comprising device stacks described with respect to FIG. 11, and/or IC devices manufactured by processes described with respect to FIGS. 12 and 13A-D. Although the described manufacturing processes include formation of nanosheet devices in one or more embodiments, other types of devices, e.g., nanowire, FinFET, planar, or the like, are within the scopes of various embodiments. The described manufacturing processes and/or orders of operations are examples. Other manufacturing processes and/or orders of operations are within the scopes of various embodiments.

FIG. 14 is a cross-section of a cell region 1400, in accordance with some embodiments in which first, second, and third orthogonal directions are parallel to the X-axis, Z-axis, and Y-axis that includes groups of stacked transistor components 1402(1)-1402(5) forming a series of CFET stacks in which each group of transistor components represents a transistor.

The cell region 1400 includes an active region 1404N (e.g., N-type) over an active region 1404P (e.g., P-type); lower metal-to-gate (MG) contacts 1412(1)-1412(5); upper MG contacts 1410(1)-1410(3) over corresponding lower MG contacts 1412(1), 1412(2) and 1412(5); upper dummy gate (DG) contacts 1414(1)-1414(2) over corresponding lower MG contacts 1412(1)-1412(2); upper metal-to-source/drain (MD) contacts 1424(1)-1424(6) over corresponding lower MD contacts 1426(1)-1426(6); instances of an MG-to-MG (G2G) contact 1411 between upper MG contacts 1410(1)-1410(2) and corresponding lower MG contacts 1412(1)-1412(2); and instances of an insulator 1406 between (A) upper MG contact 1410(3) and lower MG contact 1412(5), (B) upper DG contacts 1414(1)-1414(2) and corresponding lower MG contacts 1412(3)-1413(4), and (C) upper MD contacts 1424(1)-1424(6) and corresponding lower MD contacts 1426(1)-1426(6).

In FIG. 14, examples of the upper groups include: upper MG contact 1410(1), upper MD contacts 1424(1)-1424(2) and a corresponding portion of active region 1404N which represent a first instance of the first active transistor (e.g., a first NFET) and is included in CFET stack 1402(1); upper MG contact 1410(2), upper MD contacts 1424(2)-1424(3) and a corresponding portion of active region 1404N which represent a second instance of the first active transistor (e.g., a second NFET) included CFET stack 1402(2); upper MG contact 1410(3), upper MD contacts 1424(5)-1424(6) and a corresponding portion of active region 1404N which represent a third instance of the first active transistor (e.g., a third NFET) included CFET stack 1402(5); upper DG contact 1414(1), upper MD contacts 1424(3)-1424(4) and a corresponding portion of active region 1404N which represent a first dummy transistor CFET stack 1402(3); and upper DG contact 1414(2), upper MD contacts 1424(4)-1424(5) and a corresponding portion of active region 1404N which represent a second dummy transistor included CFET stack 1402(4).

In FIG. 14, examples of the lower groups include: lower MG contact 1412(1), lower MD contacts 1426(1)-1426(2) and a corresponding portion of active region 1404P which represent a first instance of the second active transistor (e.g., a first PFET) included CFET stack 1402(1); lower MG contact 1412(2), lower MD contacts 1426(2)-1426(3) and a corresponding portion of active region 1404P which represent a second instance of the second active transistor (e.g., a second PFET) included in CFET stack 1402(2); lower MG contact 1412(3), lower MD contacts 1426(3)-1426(4) and a corresponding portion of active region 1404P which represent a third instance of the second active transistor (e.g., a third PFET) included in CFET stack 1402(3); lower MG contact 1412(4), lower MD contacts 1426(4)-1426(5) and a corresponding portion of active region 1404P which represent a fourth instance of the second active transistor (e.g., a fourth PFET) included in CFET stack 1402(4); and lower MG contact 1412(5), lower MD contacts 1426(5)-1426(6) and a corresponding portion of active region 1404P which represent a fifth instance of the second active transistor (e.g., a fifth PFET) included in CFET stack 1402(5). In some embodiments, lower active region 1404P has an N-type dopant and upper active region 1404N has a P-type dopant.

The cell region 1400 further includes: upper isolation dummy gates (IDGs) 1418(1)-1418(2) over corresponding lower IDGs 1420(1)-1420(2); and instances of an insulator 1406 between upper IDGs 1418(1)-1418(2) and corresponding lower IDGs 1420(1)-1420(2). In some embodiments, an upper IDG is aligned over a lower MG contact. In some embodiments, a lower IDG is aligned under an upper MG contact.

In some embodiments, an isolation dummy gate (e.g., each of upper IDGs 1418(1)-1418(2) and lower IDGs 1420(1)-1420(2)) is a dielectric structure that includes one or more dielectric materials and functions as an electrical isolation structure. Accordingly, an isolation dummy gate is not a structure that is electrically conductive and thus does not function, e.g., as an active gate of a transistor. In some embodiments, the isolation dummy gates include one or more dielectric materials and functions as an electrical isolation structure. In some embodiments, an isolation dummy gate is based on a gate structure as a precursor. In some embodiments, a dummy gate structure includes a gate conductor, a gate-insulator layer, (optionally) one or more spacers, or other structures. In some embodiments, an isolation dummy gate is formed by first forming an upper MG contact or a lower MG contact, sacrificing/removing (e.g., etching) the upper or lower MG contact to form a trench, (optionally) removing a portion of an active region (e.g., active region 1404N or 1404P) that was formerly surrounded by the corresponding the upper or lower MG contact to deepen the trench, and then filling the trench with one or more dielectric materials such that the physical dimensions of the resultant electrical isolation structure, i.e., the upper or lower IDG, are similar to the dimensions of the upper or lower MG contact which was sacrificed. In some embodiments, an upper or lower IDG is a dielectric feature that includes one or more dielectric materials (e.g., oxide, nitride, oxynitride, or other suitable materials), and functions as an isolation feature. In some embodiments, an upper or lower IDG is a continuous polysilicon on oxide diffusion (OD) edge structure and is sometimes referred to as an upper or lower CPODE structure. In some embodiments, an upper or lower IDG is a non-continuous polysilicon on oxide diffusion (OD) edge structure and is sometimes referred to as an upper or lower PODE structure.

Aspects of this description relate to a semiconductor device. The semiconductor device includes an intermediate layer. The intermediate layer includes a plurality of conductive structures; and a plurality of isolation structures. The semiconductor device further includes a first array of active regions on a first side of the intermediate layer. The semiconductor device further includes a plurality of first gate structures, wherein corresponding first gate structures of the plurality of first gate structures are between adjacent active regions of the first array of active regions. The semiconductor device further includes a second array of active regions on a second side of the intermediate layer, wherein the second side is opposite the first side. The semiconductor device further includes a plurality of second gate structures, wherein corresponding second gate structures of the plurality of second gate structures are between adjacent active regions of the second array of active regions, each of the plurality of second gates is aligned with a corresponding first gate of the plurality of first gates, and a corresponding isolation structure of the plurality of isolation structures is between aligned first and second gate structures. In some embodiments, each active region of the first array of active regions has a same dopant type. In some embodiments, the semiconductor device further includes an array of low resistance regions on the second side of the intermediate layer. In some embodiments, low resistance regions of the array of low resistance regions are in an alternating pattern with active regions of the second array of active regions on the second side of the intermediate layer. In some embodiments, each low resistance region of the array of low resistance regions is aligned with a corresponding active region of the first array of active regions. In some embodiments, a corresponding conductive structure of the plurality of conductive structures is between aligned low resistance regions and active regions of the first array of active regions. In some embodiments, each active region of the second array of active regions is aligned with a corresponding active region of the first array of active regions. In some embodiments, a corresponding isolation structure of the plurality of isolation structures is between aligned active regions of the second array of active regions and active regions of the first array of active regions. In some embodiments, a first active region of the first array of active regions has a different dopant type from a second active regio of the first array of active regions. In some embodiments, the semiconductor device further includes a tap via between the first active region and the second active region, wherein the tap via extends continuously from the first side of the intermediate layer to the second side of the intermediate layer. In some embodiments, a third active region of the second array of active regions is aligned with the first active region, and a fourth active region of the second array of active regions is aligned with the second active region. In some embodiments, the third active region has a same dopant type as the first active region. In some embodiments, a first conductive structure of the plurality of conductive structures is between the third active region and the first active region. In some embodiments, the fourth active region has a different dopant type from the second active region. In some embodiments, a first conductive structure of the plurality of conductive structures is between the second active region and the fourth active region. In some embodiments, a first isolation structure of the plurality of isolation structures is between the second active region and the fourth active region.

Aspects of this description relate to a semiconductor device. The semiconductor device includes an intermediate layer. The intermediate layer includes a plurality of conductive structures; and a plurality of isolation structures. The semiconductor device further includes a first array of active regions on a first side of the intermediate layer. The semiconductor device further includes a second array of active regions on a second side of the intermediate layer, wherein the second side is opposite the first side, wherein each active regio of the second array of active regions is aligned with a corresponding active region of the first array of active regions with the intermediate layer therebetween. Aligned active regions of the first array of active region and the second array of active regions are configured to define a tap structure or of an N on P structure. In some embodiments, the semiconductor device further includes a first gate structure on the first side of the intermediate layer, wherein the first gate structure is between the tap structure and an adjacent N on P structure; and a second gate structure on the second side of the intermediate layer, wherein the second gate structure is aligned with the first gate structure. In some embodiments, an isolation structure of the plurality of isolation structures is between the first gate structure and the second gate structure.

Aspects of this description relate to a method of making a semiconductor device. The method includes forming an intermediate layer. Forming the intermediate layer includes forming a plurality of conductive structures; and forming a plurality of isolation structures. The method further includes doping a first semiconductor layer to define a first array of active regions on a first side of the intermediate layer. The method further includes forming a plurality of first gate structures on the first side of the intermediate layer. The method further includes doping a second semiconductor layer to define a second array of active regions on a second side of the intermediate layer, wherein the second side is opposite the first side. The method further includes forming a plurality of second gate structures on the second side of the intermediate layer, wherein corresponding second gate structures of the plurality of second gate structures are between adjacent active regions of the second array of active regions. The method further includes isolating aligned first and second gate structures using the plurality of isolation structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

We claim:

1. A semiconductor device comprising:
an intermediate layer, wherein the intermediate layer comprises:
a plurality of conductive structures; and
a plurality of isolation structures;
a first array of active regions on a first side of the intermediate layer;
a plurality of first gate structures, wherein corresponding first gate structures of the plurality of first gate structures are between adjacent active regions of the first array of active regions;
a second array of active regions on a second side of the intermediate layer, wherein the second side is opposite the first side; and
a plurality of second gate structures, wherein corresponding second gate structures of the plurality of second gate structures are between adjacent active regions of the second array of active regions, each of the plurality of second gates is aligned with a corresponding first gate of the plurality of first gates, and a corresponding isolation structure of the plurality of isolation structures is between aligned first and second gate structures.

2. The semiconductor device of claim 1, wherein each active region of the first array of active regions has a same dopant type.

3. The semiconductor device of claim 2, further comprising an array of low resistance regions on the second side of the intermediate layer.

4. The semiconductor device of claim 3, wherein low resistance regions of the array of low resistance regions are in an alternating pattern with active regions of the second array of active regions on the second side of the intermediate layer.

5. The semiconductor device of claim 3, wherein each low resistance region of the array of low resistance regions is aligned with a corresponding active region of the first array of active regions.

6. The semiconductor device of claim 5, wherein a corresponding conductive structure of the plurality of conductive structures is between aligned low resistance regions and active regions of the first array of active regions.

7. The semiconductor device of claim 3, wherein each active region of the second array of active regions is aligned with a corresponding active region of the first array of active regions.

8. The semiconductor device of claim 7, wherein a corresponding isolation structure of the plurality of isolation structures is between aligned active regions of the second array of active regions and active regions of the first array of active regions.

9. The semiconductor device of claim 1, wherein a first active region of the first array of active regions has a different dopant type from a second active regio of the first array of active regions.

10. The semiconductor device of claim 9, further comprising a tap via between the first active region and the second active region, wherein the tap via extends continuously from the first side of the intermediate layer to the second side of the intermediate layer.

11. The semiconductor device of claim 9, wherein a third active region of the second array of active regions is aligned with the first active region, and a fourth active region of the second array of active regions is aligned with the second active region.

12. The semiconductor device of claim 11, wherein the third active region has a same dopant type as the first active region.

13. The semiconductor device of claim 12, wherein a first conductive structure of the plurality of conductive structures is between the third active region and the first active region.

14. The semiconductor device of claim 11, wherein the fourth active region has a different dopant type from the second active region.

15. The semiconductor device of claim 14, wherein a first conductive structure of the plurality of conductive structures is between the second active region and the fourth active region.

16. The semiconductor device of claim 14, wherein a first isolation structure of the plurality of isolation structures is between the second active region and the fourth active region.

17. A semiconductor device comprising:
an intermediate layer, wherein the intermediate layer comprises:
a plurality of conductive structures; and
a plurality of isolation structures;
a first array of active regions on a first side of the intermediate layer;
a second array of active regions on a second side of the intermediate layer, wherein the second side is opposite the first side, wherein each active regio of the second array of active regions is aligned with a corresponding active region of the first array of active regions with the intermediate layer therebetween, and
aligned active regions of the first array of active region and the second array of active regions are configured to define a tap structure or of an N on P structure.

18. The semiconductor device of claim 17, further comprising:
a first gate structure on the first side of the intermediate layer, wherein the first gate structure is between the tap structure and an adjacent N on P structure; and
a second gate structure on the second side of the intermediate layer, wherein the second gate structure is aligned with the first gate structure.

19. The semiconductor structure of claim 18, wherein an isolation structure of the plurality of isolation structures is between the first gate structure and the second gate structure.

20. A method of making a semiconductor device, the method comprising:
forming an intermediate layer, wherein forming the intermediate layer comprises:
forming a plurality of conductive structures; and
forming a plurality of isolation structures;
doping a first semiconductor layer to define a first array of active regions on a first side of the intermediate layer;
forming a plurality of first gate structures on the first side of the intermediate layer;
doping a second semiconductor layer to define a second array of active regions on a second side of the intermediate layer, wherein the second side is opposite the first side;
forming a plurality of second gate structures on the second side of the intermediate layer, wherein corresponding second gate structures of the plurality of second gate structures are between adjacent active regions of the second array of active regions; and
isolating aligned first and second gate structures using the plurality of isolation structures.
